(19) United States
(12) Patent Application Publication
(10) Pub. No.: US 2026/0157228 A1
(43) Pub. Date: Jun. 4, 2026

(54) PACKAGE, SEMICONDUCTOR MODULE, AND PACKAGE MANUFACTURING METHOD

(71) Applicants: NGK ELECTRONICS DEVICES, INC., Mine-shi (JP); NGK INSULATORS, LTD., Nagoya-shi (JP)

(72) Inventors: Masakazu SATO, Sanyo-Onoda-shi (JP); Akiyoshi OSAKADA, Mine-shi (JP); Yoshikazu MIHARA, Shimonoseki-shi (JP)

(21) Appl. No.: 19/464,817

(22) Filed: Jan. 30, 2026

Related U.S. Application Data
(63) Continuation of application No. PCT/JP2024/002405, filed on Jan. 26, 2024.

(30) Foreign Application Priority Data
Jul. 31, 2023 (WO) PCT/JP2023/027952

(51) Int. Cl. H10W 76/157; H10W 40/20; H10W 76/01; H10W 76/63; H10W 90/00

(52) U.S. Cl. CPC H10W 76/157; H10W 40/233; H10W 76/63; H10W 76/01; H10W 90/757

(57) ABSTRACT

A package has a cavity and includes a heat dissipating plate and a ceramic frame. The heat dissipating plate is formed of a first sintered material containing a metal and has a main surface including a cavity surface facing the cavity, a heat dissipating surface opposite the main surface, and a side surface between the heat dissipating surface and the main surface. The ceramic frame has an inner surface surrounding the cavity and an outer surface opposite the inner surface. The main surface of the heat dissipating plate includes a joined surface directly joined to the ceramic frame.

### CROSS-REFERENCE TO RELATED APPLICATION

This application is a continuation application of PCT/JP 2024/002405, filed on Jan. 26, 2024, which claims the benefit of priority of International Patent Application No. PCT/JP 2023/027952, filed on Jul. 31, 2023, the entire contents of which are incorporated herein by reference.

### BACKGROUND

### Technical Field

The present invention relates to a package, a semiconductor module, and a package manufacturing method.

### Description of the Background Art

Japanese Patent Application Laid-Open No. 2015-204426 discloses a package. The package includes a heat sink plate and a ceramic frame. The heat sink plate is a rectangular metal plate and is for radiating heat generated from an electronic component mounted to an upper surface thereof. The ceramic frame is joined to the heat sink plate to surround a site where the electronic component is mounted. They are joined by brazing. A brazing temperature is approximately 780° C. The ceramic frame is formed of alumina or aluminum nitride, for example.

The above-mentioned ceramic frame has a frame shape and includes a joined body of an upper layer sheet and a lower layer sheet. A metallization film and a plating coating are arranged on a lower surface of the lower layer sheet. The plating coating on the lower surface of the lower layer sheet and the heat sink plate are joined together via a brazing material. An inner peripheral end of the lower layer sheet is located further offset toward an outer periphery than an inner peripheral end of the upper layer sheet is. The electronic component can thus be mounted while avoiding a fillet of the brazing material even when the electronic component is brought close to an inner periphery of the upper layer sheet of the ceramic frame.

The above-mentioned heat sink plate is a metal plate. Selected as the metal plate is a metal plate having high thermal conductivity and capable of mitigating warpage of the package caused by a difference in coefficient of linear expansion from the ceramic frame during brazing. A composite metal plate or a clad metal plate is used, for example. The composite metal plate is formed by impregnation, for example. Specifically, it is formed by impregnating a porous refractory metal plate with Cu. A refractory metal, such as tungsten (W) and molybdenum (Mo), has a close coefficient of linear expansion to ceramics, so that the heat sink plate can have a closer coefficient of linear expansion to the ceramic frame. Cu has excellent thermal conductivity, so that heat dissipating performance of the heat sink plate can be increased.

When the heat sink plate is required to have a closer coefficient of linear expansion to the ceramic frame, the composite metal plate or the clad metal plate is widely used as described above. When a match between coefficients of linear expansion is not important, a simple metal material is widely used, and thermal conductively can significantly be increased by using pure copper, for example. As a heat sink plate (i.e., a heat dissipating plate or a heat dissipating substrate) for a semiconductor light-emitting element, a heat sink plate containing metal oxide is also proposed as described below.

According to Japanese Patent Application Laid-Open No. 2009-88205, a heat dissipating substrate includes an element assembly containing metal oxide as a major component and a plurality of metal masses arranged throughout the element assembly and having flaky portions. The plurality of metal masses are characterized in that thickness directions thereof are the same predetermined direction. Due to these characteristics, anisotropy of thermal conductivity appears. Examples of the above-mentioned metal oxide include ZnO, Al₂O₃, SiO₂, and ZrO₂. ZnO is white to be able to reflect more light from a semiconductor light-emitting element. When the metal masses are formed of silver or a silver alloy, use of ZnO as the metal oxide increases flexibility of the heat dissipating substrate to make the heat dissipating substrate less likely to break. A method of manufacturing this heat dissipating substrate includes: preparing a slurry in which flaky metal powder and the metal oxide are dispersed; forming a green sheet by applying the slurry onto a film through a doctor blade technique; and firing the green sheet.

A size of the package is typically limited. To locate the inner peripheral end of the lower layer sheet further offset toward the outer periphery than the inner peripheral end of the upper layer sheet is as in technology disclosed in Japanese Patent Application Laid-Open No. 2015-204426 described above under such a limitation, a width dimension (a dimension between an inner periphery and the outer periphery) of the frame shape of the lower layer sheet is required to be reduced. As a result, sealing reliability or ease of manufacture of the package is likely to be reduced. From the foregoing, technology for mounting an electronic component (typically a semiconductor element) so that the electronic component is close to the frame while an extremely small width dimension (dimension between the inner periphery and the outer periphery) of the frame is avoided is required.

### SUMMARY

The present invention has been conceived to solve a problem as described above, and it is an object of the present invention to provide a package, a semiconductor module, and a package manufacturing method that enable mounting a semiconductor element so that the semiconductor element is close to a frame while an extremely small width dimension of the frame is avoided.

Aspect 1 is a package having a cavity, and the package includes a heat dissipating plate and a ceramic frame. The heat dissipating plate is formed of a first sintered material containing a metal and has a main surface including a cavity surface facing the cavity, a heat dissipating surface opposite the main surface, and a side surface between the heat dissipating surface and the main surface. The ceramic frame has an inner surface surrounding the cavity and an outer surface opposite the inner surface. The main surface of the heat dissipating plate includes a joined surface directly joined to the ceramic frame.

Aspect 2 is the package according to Aspect 1, wherein the side surface of the heat dissipating plate is not directly joined to the ceramic frame.

Aspect 3 is the package according to Aspect 1 or 2, wherein the first sintered material is a sintered metal material.

Aspect 4 is the package according to Aspect 1 or 2, wherein the first sintered material contains copper and at least one refractory metal selected from the group consisting of tungsten and molybdenum.

Aspect 5 is the package according to Aspect 4, wherein in a cross section of at least a portion of the joined surface, the joined surface macroscopically extends along a straight line and microscopically defines an irregular boundary between the heat dissipating plate and the ceramic frame, the boundary includes a copper section formed of the copper and a refractory metal section formed of the at least one refractory metal, and a ratio of the refractory metal section in a projection of the boundary onto the straight line is greater than a volume ratio of the at least one refractory metal in the heat dissipating plate.

Aspect 6 is the package according to Aspect 4 or 5, further including a metallization layer disposed on an upper surface of the ceramic frame and formed of a second sintered material containing copper in a higher volume ratio than the first sintered material for the heat dissipating plate.

Aspect 7 is the package according to any one of Aspects 1 to 6, wherein the ceramic frame contains Mn, in an Mn element distribution map, the ceramic frame includes a layer portion in a depth range of 3 μm including a position at a depth of 3 μm or less from the joined surface into the ceramic frame and a bulk portion in a depth range of 3 μm including a position at a depth of 6 μm or more and 9 μm or less from the joined surface into the ceramic frame, and an Mn element concentration is higher in the layer portion than in the bulk portion.

Aspect 8 is the package according to any one of Aspects 1 to 6, wherein the ceramic frame contains Mn, the ceramic frame includes a layer portion located at a depth of 3 μm or less from the joined surface and a bulk portion separated from the joined surface by the layer portion, and an Mn concentration profile for a depth from the joined surface into the ceramic frame includes a maximum peak located in the layer portion.

Aspect 9 is the package according to Aspect 8, wherein in the Mn concentration profile for the depth, the maximum peak is 150% or more of a representative value in the bulk portion.

Aspect 10 is the package according to any one of Aspects 1 to 9, wherein the joined surface of the heat dissipating plate does not contain silver.

Aspect 11 is the package according to any one of Aspects 1 to 10, wherein the side surface of the heat dissipating plate is connected to the outer surface of the ceramic frame.

Aspect 12 is the package according to Aspect 11, wherein the side surface of the heat dissipating plate is flatly connected to the outer surface of the ceramic frame.

Aspect 13 is the package according to any one of Aspects 1 to 12, wherein the main surface of the heat dissipating plate and the outer surface of the ceramic frame form an acute angle.

Aspect 14 is the package according to any one of Aspects 1 to 13, wherein the ceramic frame has an upper surface separated from the main surface of the heat dissipating plate by the ceramic frame and connected to the outer surface, and a corner of the upper surface of the ceramic frame and the outer surface of the ceramic frame has a radius of curvature of 0.1 mm or more and 0.5 mm or less.

Aspect 15 is the package according to any one of Aspects 1 to 14, further including a metal terminal disposed on an upper surface of the ceramic frame.

Aspect 16 is a semiconductor module including: the package according to any one of Aspects 1 to 15; and a semiconductor element mounted to the cavity surface of the main surface of the heat dissipating plate. A distance between the semiconductor element and the inner surface of the ceramic frame is 25 μm or less.

Aspect 17 is a package manufacturing method for manufacturing a package having a cavity including: forming a green structure in which a first green member to be a heat dissipating plate by being fired and a second green member to be a ceramic frame by being fired are combined; and firing the green structure.

Aspect 18 is the package manufacturing method according to Aspect 17, wherein the forming of the green structure includes forming the second green member, and the forming of the second green member includes removing a portion corresponding to the cavity from a green sheet to be at least a portion of the second green member.

Aspect 19 is the package manufacturing method according to Aspect 17 or 18, wherein the first green member is formed using first metal powder containing copper and at least one refractory metal selected from the group consisting of tungsten and molybdenum. The green structure includes an additional layer to be a metallization layer on an upper surface of the ceramic frame by being fired, and the additional layer is formed using second metal powder containing copper and at least one refractory metal selected from the group consisting of tungsten and molybdenum. The second metal powder contains copper in a higher volume ratio than the first metal powder.

According to the aspect described above, the ceramic frame and the heat dissipating plate are directly joined together. This eliminates the need for a brazing material to join the ceramic frame and the heat dissipating plate together. Interference of the brazing material flowing into the cavity with mounting of the semiconductor element is thus avoided. The semiconductor element can thus be mounted close to the ceramic frame.

These and other objects, features, aspects, and advantages of the present invention will become more apparent from the following detailed description when taken in conjunction with the accompanying drawings.

### BRIEF DESCRIPTION OF THE DRAWINGS

FIG. 1 is a schematic perspective view showing a configuration of a semiconductor module according to Embodiment 1 with a portion thereof omitted so that the interior of a cavity is visible;

FIG. 2 is a schematic cross-sectional view of the semiconductor module taken along the line II-II of FIG. 1;

FIG. 3 is a schematic cross-sectional view showing a configuration of a package as a component of the semiconductor module of FIG. 2;

FIG. 4 is a flowchart schematically showing a method of manufacturing the package of FIG. 3;

FIG. 5 is a schematic partial cross-sectional view showing one step of the method of manufacturing the package of FIG. 3;

FIG. 6 is a schematic partial cross-sectional view showing one step of the method of manufacturing the package of FIG. 3;

FIG. 7 is a schematic partial cross-sectional view showing one step of the method of manufacturing the package of FIG. 3;

FIG. 8 is a schematic partial cross-sectional view showing one step of the method of manufacturing the package of FIG. 3;

FIG. 9 is a schematic cross-sectional view showing a configuration of a package according to a comparative example;

FIG. 10 is a schematic cross-sectional view showing a configuration of a semiconductor module including the package of FIG. 9;

FIG. 11 is a schematic partial cross-sectional view showing a first example in which a side surface of a heat dissipating plate and an outer surface of a ceramic frame are flatly connected to each other;

FIG. 12 is a schematic partial cross-sectional view showing a second example in which the side surface of the heat dissipating plate and the outer surface of the ceramic frame are flatly connected to each other;

FIG. 13 is a schematic partial cross-sectional view showing a third example in which the side surface of the heat dissipating plate and the outer surface of the ceramic frame are flatly connected to each other;

FIG. 14 is a schematic partial cross-sectional view showing a package according to a first modification of FIG. 11;

FIG. 15 is a schematic partial cross-sectional view showing a package according to a second modification of FIG. 11;

FIG. 16 is a schematic partial cross-sectional view showing a joining strength test conducted on the heat dissipating plate and the ceramic frame;

FIG. 17 is a schematic cross-sectional view showing a configuration of a heat dissipating plate and a ceramic frame of the package according to Embodiment 1;

FIG. 18 is a schematic cross-sectional view showing a configuration of a package according to Embodiment 2 in a similar view to that in FIG. 17;

FIG. 19 is a schematic cross-sectional view showing a configuration of a package according to Embodiment 3 in a similar view to that in FIG. 17;

FIG. 20 is a schematic cross-sectional view showing a configuration of a package according to Embodiment 4 in a similar view to that in FIG. 17;

FIG. 21 is a schematic cross-sectional view showing a configuration of a package according to Embodiment 5 in a similar view to that in FIG. 17;

FIG. 22 is a schematic cross-sectional view showing a configuration of a package according to Embodiment 6 in a similar view to that in FIG. 17;

FIG. 23 is an electron micrograph showing a cross section of a portion of a joined surface of the heat dissipating plate to the ceramic frame according to Embodiment 1;

FIG. 24 is a diagram showing, while the joined surface macroscopically extends along a straight line and microscopically defines an irregular boundary between the heat dissipating plate and the ceramic frame in a cross section of at least a portion of the joined surface, a projection of the boundary onto the straight line;

FIG. 25 is a diagram showing Cu element distribution (bottom) near the joined surface of the heat dissipating plate to the ceramic frame together with an electron micrograph (top) corresponding to a view in the distribution map;

FIG. 26 is a diagram showing W element distribution (bottom) near the joined surface of the heat dissipating plate to the ceramic frame together with an electron micrograph (top) corresponding to a view in the distribution map;

FIG. 27 is a diagram showing Mn element distribution (bottom) near the joined surface of the heat dissipating plate to the ceramic frame together with an electron micrograph (top) corresponding to a view in the distribution map;

FIG. 28 is a diagram showing a layer portion and a bulk portion for the Mn element distribution shown at the bottom of FIG. 27;

FIG. 29 is a graph (top) showing a depth profile of a count by SEM-EDX in an Mn element analysis together with the electron micrograph shown in FIG. 27 to which a rectangular region corresponding to the profile has been added (bottom) and the region (middle) disposed to match a horizontal axis of the graph;

FIG. 30 is a graph (top) showing a depth profile of a count by SEM-EDX in the Mn element analysis together with the electron micrograph shown in FIG. 27 to which a rectangular region corresponding to the profile has been added (bottom) and the region (middle) disposed to match a horizontal axis of the graph;

FIG. 31 is a graph (top) showing a depth profile of a count by SEM-EDX in the Mn element analysis together with the electron micrograph shown in FIG. 27 to which a rectangular region corresponding to the profile has been added (bottom) and the region (middle) disposed to match a horizontal axis of the graph;

FIG. 32 is a graph (top) showing a depth profile of a count by SEM-EDX in the Mn element analysis together with the electron micrograph shown in FIG. 27 to which a rectangular region corresponding to the profile has been added (bottom) and the region (middle) disposed to match a horizontal axis of the graph; and

FIG. 33 is a graph (top) showing a depth profile of a count by SEM-EDX in the Mn element analysis together with the electron micrograph shown in FIG. 27 to which a rectangular region corresponding to the profile has been added (bottom) and the region (middle) disposed to match a horizontal axis of the graph.

### DESCRIPTION OF THE PREFERRED EMBODIMENTS

Embodiments of the present invention will be described below with reference to the accompanying drawings. A metal can herein mean both a pure metal and an alloy unless otherwise noted. Wording “green” means a state before firing. A member with the wording “green” is thus to be fired but has not yet been fired.

### Embodiment 1

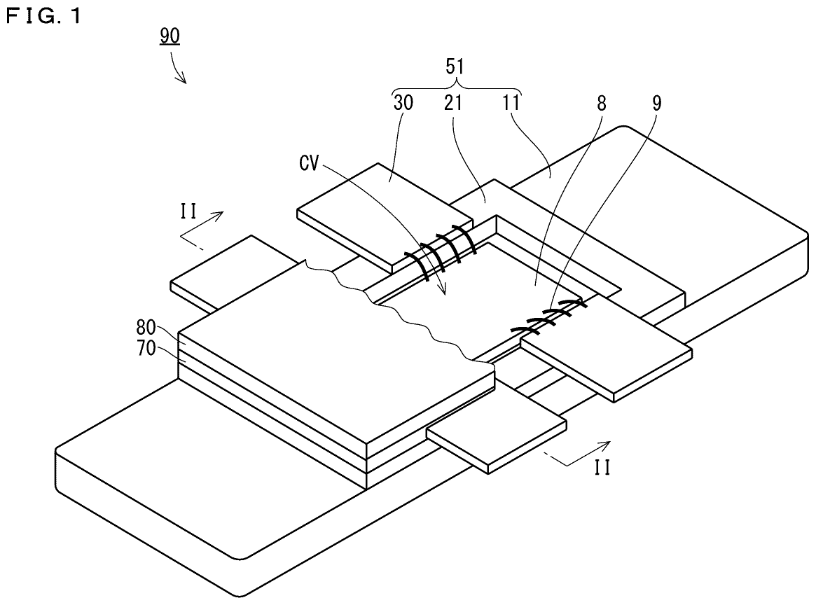

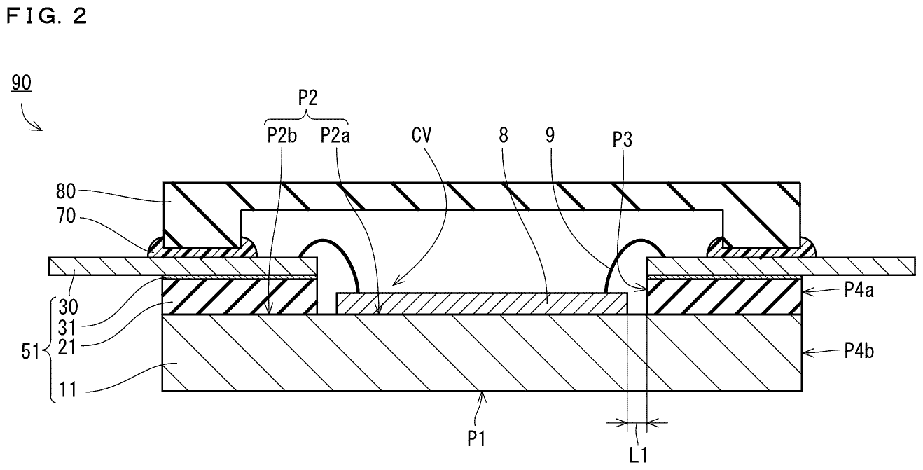

FIG. 1 is a schematic perspective view showing a configuration of a semiconductor module 90 according to Embodiment 1. FIG. 2 is a schematic cross-sectional view of the semiconductor module 90 taken along the line II-II of FIG. 1. The semiconductor module 90 includes a package 51 and a semiconductor element 8. The semiconductor module 90 may include wires 9 as wiring members for the semiconductor element 8. The semiconductor module 90 may include a lid 80 for sealing a cavity CV. The lid 80 may be attached to the package 51 by an adhesive layer 70. Portions of the lid 80 and the adhesive layer 70 are not illustrated in FIG. 1, so that the interior of the cavity CV of the package 51 is partially visible.

The semiconductor element 8 may be a power semiconductor element, and, in this case, the semiconductor module 90 is a power module. The power semiconductor element may be for radio frequency (RF), and, in this case, the semiconductor module 90 is an RF power module. While one semiconductor element 8 is illustrated in each of FIGS. 1 and 2, a plurality of semiconductor elements 8 may be mounted to the package 51. An element other than the semiconductor element 8, such as a passive element, may be mounted.

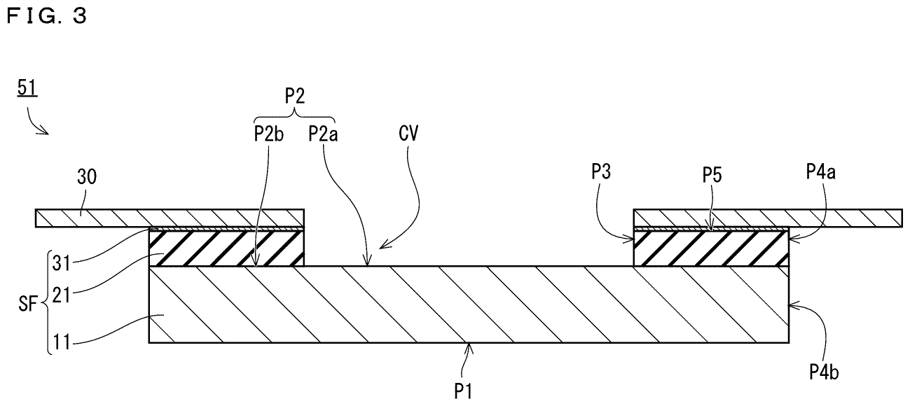

FIG. 3 is a schematic cross-sectional view showing a configuration of the package 51 as a component of the semiconductor module 90 (FIG. 2). At a point in time when the package 51 is prepared for manufacture of the semiconductor module 90, the semiconductor element 8 may not yet be mounted as illustrated in FIG. 3. The package 51 has the cavity CV to be sealed with the lid 80. The package 51 includes a heat dissipating plate 11 and a ceramic frame 21.

The heat dissipating plate 11 is formed of a first sintered material containing a metal. For example, the first sintered material contains copper (Cu) and a refractory metal. The refractory metal has a higher melting point than Cu.< The refractory metal may be at least any of tungsten (W) and molybdenum (Mo). The first sintered material may thus contain Cu and at least one refractory metal selected from the group consisting of W and Mo. While a case where the refractory metal is W will mainly be described as an example in description made below, Mo may be used in place of or in addition to W. The first sintered material is not required to contain a non-metal. In other words, the first sintered material may be a sintered metal material. In other words, the first sintered material may be a sintered material substantially formed of a metal. The sintered metal material may contain Cu and W and may be an alloy of Cu and W, that is, a copper tungsten alloy. As a modification, the first sintered material may contain the non-metal. The non-metal may be ceramics, such as Al₂O₃, SiO₂, and ZrO₂.

A material for the heat dissipating plate 11 preferably has high thermal conductivity to increase heat dissipating performance of the heat dissipating plate 11. Such high thermal conductivity is easily obtained when the heat dissipating plate 11 contains Cu in a sufficient ratio. On the other hand, when the heat dissipating plate 11 contains W in a sufficient ratio, the heat dissipating plate 11 can have a close coefficient of linear expansion to ceramics, such as alumina. The close coefficient of linear expansion is useful for suppression of thermal stress applied between the heat dissipating plate 11 and the ceramic frame 21. When a total volume of a metal component of the heat dissipating plate 11 is defined as 100 vol %, the heat dissipating plate 11 may contain Cu of 10 vol % or more and 90 vol % or less and the refractory metal substantially as a remainder, for example. The heat dissipating plate 11 may more preferably contain Cu of 25 vol % or more and 50 vol % or less and the refractory metal substantially as a remainder.

The heat dissipating plate 11 has a heat dissipating surface P1 and a main surface P2 opposite the heat dissipating surface P1. The heat dissipating surface P1 of the heat dissipating plate 11 is typically to be attached to a support member (not illustrated). The support member is a mounting board or a heat dissipating member, for example. The heat dissipating plate 11 may have a penetrating portion (not illustrated) through which a fastener (e.g., screw) for attachment to the support member passes.

The ceramic frame 21 is a frame formed of ceramics. Use of the ceramic frame 21 as a frame of the package 51 can increase thermal resistance and insulation of the package 51. A material for the ceramic frame 21 may contain alumina (Al₂O₃) as a major component, may contain a trace amount of silica (SiO₂) to promote sintering of the ceramic frame 21, and may contain an additive containing an Mn element. Another component may also be contained. Raw material powder as a material for the ceramic frame 21 may be mixed powder of Al₂O₃ powder of 50 wt % or more as a major component, Si element containing powder of 5 wt % to 17 wt % in terms of SiO₂ equivalent, and Mn element containing powder of 3 wt % to 14 wt % in terms of MnO equivalent, for example. A firing temperature when the mixed powder is used is 1150° C. to 1300° C., for example.

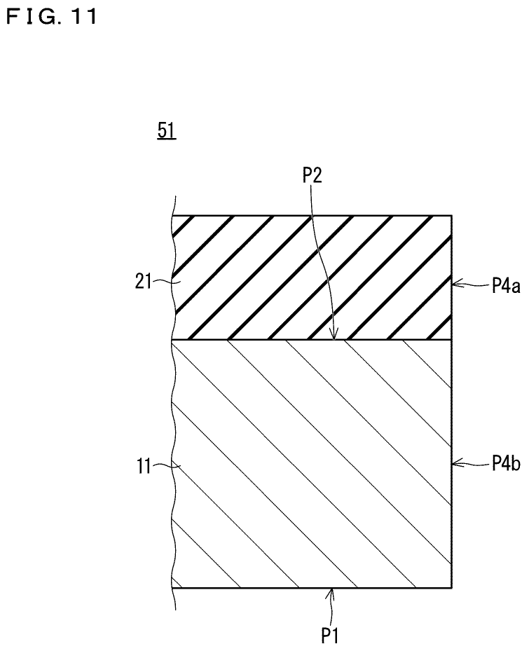

The ceramic frame 21 is disposed on the main surface P2 of the heat dissipating plate 11. The ceramic frame 21 has an inner surface P3 surrounding the cavity CV and an outer surface P4a opposite the inner surface P3. The heat dissipating plate 11 has a side surface P4b between the heat dissipating surface P1 and the main surface P2. The side surface P4b may flatly be connected to the outer surface P4a of the ceramic frame 21, which will be described in detail with reference to FIGS. 11 to 13. An outer edge of the ceramic frame 21 may have a rectangular shape as illustrated in FIG. 1 in an in-plane direction perpendicular to a thickness direction. Each side of the rectangular shape has a length of 4 mm or more and 40 mm or less, for example. The ceramic frame 21 has a thickness of 0.1 mm or more and 1 mm or less, for example.

The main surface P2 of the heat dissipating plate 11 includes a cavity surface P2a facing the cavity CV and a joined surface P2b directly joined to the ceramic frame 21. The ceramic frame 21 and the heat dissipating plate 11 are thus directly joined to each other. A silver (Ag) brazing material is thus not used for joining. The joined surface P2b of the heat dissipating plate 11 is thus not required to contain Ag.

The inventors confirmed that the ceramic frame 21 and the heat dissipating plate 11 are joined to each other with sufficient strength. It was further confirmed by light microscopy or scanning electron microscopy that the ceramic frame 21 and the heat dissipating plate 11 are directly joined to each other. An expression “directly joined” herein means that a component other than a component derived from the heat dissipating plate 11 and the ceramic frame 21 is not detected at the junction. For example, when the heat dissipating plate 11 contains Cu, and the ceramic frame 21 contains silica and/or Mn, the inventors may infer that an extremely thin reaction layer derived as described above is formed due to reaction of molten Cu to silica and/or Mn in a firing step described below. A component at the junction can be verified by energy dispersive X-ray spectroscopy (EDX), for example. EDX can be performed with a scanning electron microscope equipped with a spectroscope for EDX.

The package 51 may include a lead frame 30 (metal terminal). The lead frame 30 is disposed on an upper surface P5 of the ceramic frame 21 and is separated from the heat dissipating plate 11 by the ceramic frame 21. The upper surface P5 may be a flat surface. The lead frame 30 forms an electrical path connecting the interior and the exterior of the cavity CV. Between the lead frame 30 and the ceramic frame 21, a joining material (not illustrated) for joining them to each other may be disposed. The joining material may be formed by Ag sintering, for example, and, in this case, the above-mentioned joining material is a mixture of a thermosetting resin (e.g., an epoxy resin or a silicon resin) and Ag particles. A silver braze may be used for the joining material. In this case, a metallization layer 31 for the silver braze is typically formed on the upper surface P5 of the ceramic frame 21 in advance. As one example of a method of forming the metallization layer 31, a paste to be the metallization layer 31 is first printed on a green sheet to be the ceramic frame 21 before the firing step for forming the ceramic frame 21 and the heat dissipating plate 11 (described in detail below). Specifically, metal powder of at least any one of W, Mo, and Cu, an additive, a resin, a solvent, and the like are first mixed, and further ceramic powder is added as necessary and kneaded to prepare the paste. The paste is printed to the green sheet prepared in the preceding step by screen printing, for example. After printing, the green sheet is dried under conditions at a temperature of 110° C. and for five minutes, for example. Alternatively, the metallization layer 31 may be formed by laminating a green sheet containing a metal on the green sheet to be the ceramic frame 21 before the firing step for forming the ceramic frame 21 and the heat dissipating plate 11 (described in detail below).

The metallization layer 31 may be formed of a second sintered material containing Cu in a higher volume ratio than the above-mentioned first sintered material for the heat dissipating plate 11. In this case, the metallization layer 31 has a higher coefficient of linear expansion than the heat dissipating plate 11. In light of the thickness of the metallization layer 31 that is typically smaller than the thickness of the heat dissipating plate 11, thermal stress is likely to have a good balance in the package 51 when a configuration in which the ceramic frame 21 is disposed between the metallization layer 31 and the heat dissipating plate 11 has a relationship on the coefficient of linear expansion described above. Warpage of the package 51 when the package 51 is subjected to a temperature change can thus be suppressed. The metallization layer 31 preferably has a thickness of 5 μm or more and 200 μm or less. A thickness of 5 μm or more leads to the above-mentioned good balance of thermal stress, so that an effect of suppressing warpage of the package 51 can more sufficiently be obtained. Furthermore, a function as a conductive layer can sufficiently be obtained. A thickness of 200 μm or less makes separation of the metallization layer 31 less likely to occur.

The lid 80 (FIGS. 1 and 2) may be formed of a ceramic material, and the ceramic material may contain alumina as a major component and is substantially alumina, for example. Alternatively, the lid 80 may contain a resin. The resin is a liquid crystal polymer, for example. Inorganic fillers may be dispersed in the resin and are, for example, silica particles. Dispersion of the inorganic fillers in the resin can increase strength and durability of the lid 80.

The semiconductor element 8 (FIG. 2) is to be mounted to the cavity surface P2a (FIG. 3) of the main surface P2 of the heat dissipating plate 11 of the package 51. A distance L1 (FIG. 2) between the mounted semiconductor element 8 and the inner surface P3 of the ceramic frame 21 may be 25 μm or less. The distance L1 may be zero. In other words, the semiconductor element 8 and the inner surface P3 of the ceramic frame 21 may be in contact with each other.

The semiconductor element 8 may be mounted using a solder material (not illustrated), for example. After mounting of the semiconductor element 8, the wires 9 (FIG. 2) may be formed to electrically connect the semiconductor element 8 to the lead frame 30. They may be formed by wire bonding. The lid 80 may then be attached to the package 51. It may be attached using the adhesive layer 70. The adhesive layer 70 may be a thermosetting resin. The adhesive layer 70 is disposed on the ceramic frame 21 to surround the cavity CV. The adhesive layer 70 may include a portion disposed on the ceramic frame 21 via the lead frame 30 as illustrated in FIG. 2. The adhesive layer 70 has a thickness between the lid 80 and the package 51 of 100 μm or more and 360 μm or less, for example.

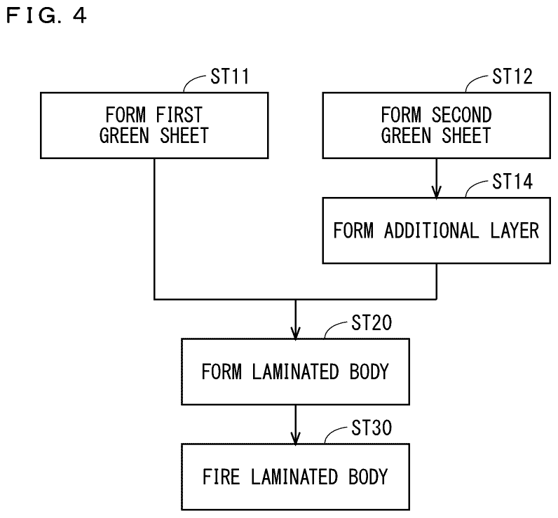

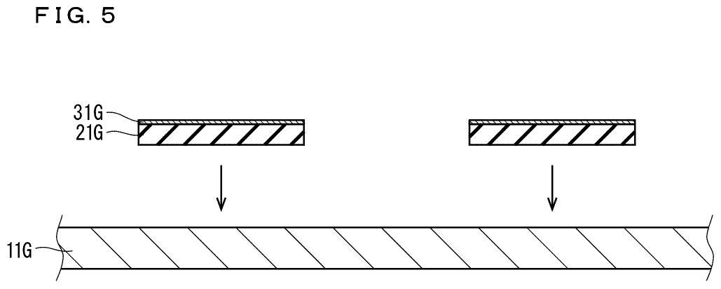

FIG. 4 is a flowchart schematically showing a method of manufacturing the package 51 (FIG. 3). FIGS. 5 to 8 are schematic partial cross-sectional views showing steps of the manufacturing method.

In step ST11 and step ST12 (FIG. 4), at least one first green sheet (first green structure) 11G (FIG. 5) and at least one second green sheet (second green structure) 21G (FIG. 5) are respectively formed. The first green sheet 11G (FIG. 5) is a green sheet to be the heat dissipating plate 11 (FIG. 3) by being fired. The second green sheet 21G (FIG. 5) is a green sheet to be the ceramic frame 21 (FIG. 3) by being fired.

To form a green sheet, a slurry is first prepared. The slurry is obtained by mixing powder to be a component of a sintered body with a resin, a plasticizer, a solvent, and the like using a ball mill. Examples of the above-mentioned powder for a slurry to form the ceramic frame 21 include Al₂O₃ powder as a major component and SiO₂ powder as a sintering aid. Examples of the above-mentioned powder for a slurry to form the first green sheet 11G to be the heat dissipating plate 11 include Cu powder and W powder. Specifically, a step of forming the first green sheet 11G may be performed using first metal powder containing Cu and at least one refractory metal selected from the group consisting of W and Mo. The first metal powder may be mixed powder of powder containing Cu and powder containing the refractory metal. The powder containing Cu may be Cu powder. The slurry is processed into the green sheet by a doctor blade method. A planar shape of the green sheet is determined according to the shape of a target component. A planar shape of the first green sheet 11G to form the heat dissipating plate 11 is typically a generally rectangular shape. A planar shape of the second green sheet 21G to form the ceramic frame 21 is a shape of a frame obtained by removing a portion corresponding to the cavity CV (FIG. 3). Specifically, the second green sheet 21G is formed, after being formed as a simple sheet by the doctor blade method, by removing the portion corresponding to the cavity CV.

In step ST14, an additional layer 31G to be the metallization layer 31 on the upper surface P5 of the ceramic frame 21 by being fired is formed on the second green sheet 21G. It may be formed using second metal powder containing Cu and at least one refractory metal selected from the group consisting of W and Mo. The second metal powder may contain Cu in a higher volume ratio than the above-mentioned first metal powder.

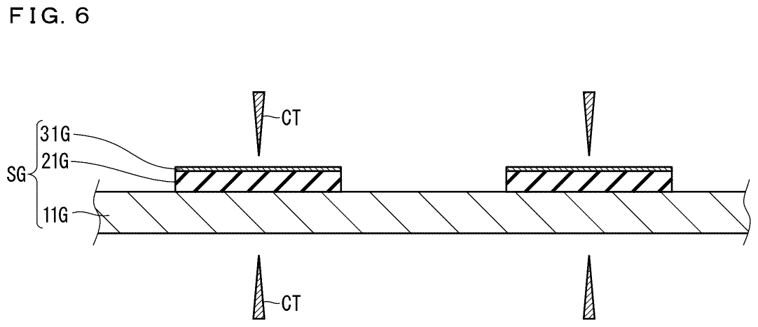

Next, in step ST20 (FIG. 4), the second green sheet 21G is laminated on the first green sheet 11G as indicated by arrows in FIG. 5. A laminated body (green structure) SG (FIG. 6) in which the first green sheet 11G and the second green sheet 21G are combined is thereby formed. In this case, pressure is only required to be applied to the green structure along a thickness direction. Next, at a position where breaking described below is performed, a trench (not illustrated) may be formed in a surface of each of the first green sheet 11G and the second green sheet 21G by machining using cutting edges CT or laser processing using a laser processing apparatus (not illustrated).

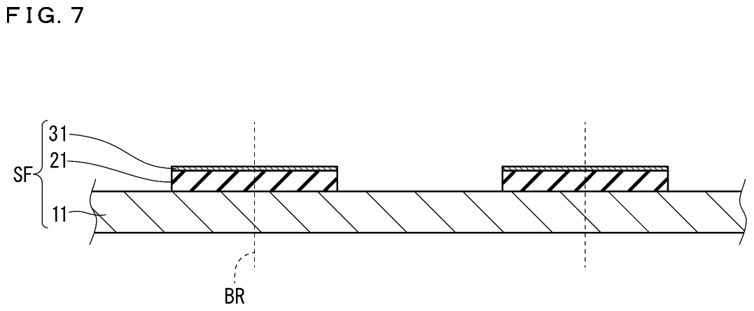

In step ST30 (FIG. 4), a laminated body SG (FIG. 6) is fired. The laminated body SG is thus changed into a fired body SF (FIG. 7). A firing temperature is 1100° C. or more and 1400° C. or less, for example. A firing temperature of 1100° C. or more enables heating of the laminated body SG to a temperature higher than a melting point of Cu. The heat dissipating plate 11 containing Cu can thus be formed with high quality. On the other hand, a firing temperature of 1400° C. or less can avoid a difficulty in a step attributable to an excessively high firing temperature.

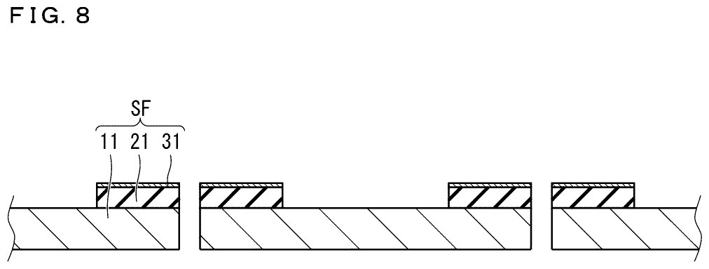

Next, a breaking step originating from the above-mentioned trench is performed as indicated by dashed lines BR (FIG. 7). As a result, the fired body SF is divided into a plurality of portions (FIG. 8). A plurality of fired bodies SF corresponding to a plurality of packages 51 (FIG. 3) are thus obtained (FIG. 8).

Next, the lead frame 30 (FIG. 3) is attached to each of the fired bodies SF. The package 51 (FIG. 3) is thus obtained.

In the above-mentioned manufacturing method, plating may be performed at an appropriate timing after the firing step. The above-mentioned manufacturing method is one example as described above, and various modifications are applicable. For example, cutting may be performed on the laminated body SG before firing instead of performing the breaking step on the fired body SF. While the semiconductor element 8 (FIG. 2) is mounted at a timing after the breaking step according to the above-mentioned manufacturing method, mounting may be performed not at the timing but at a timing after the firing step and before the breaking step.

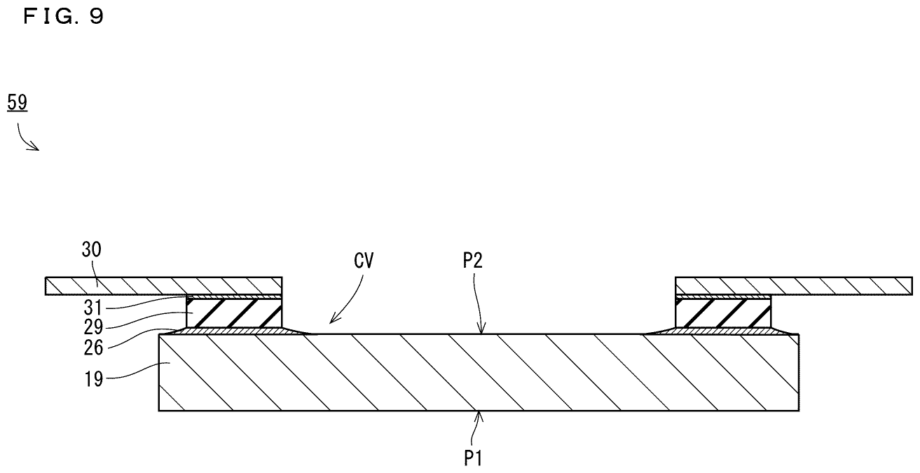

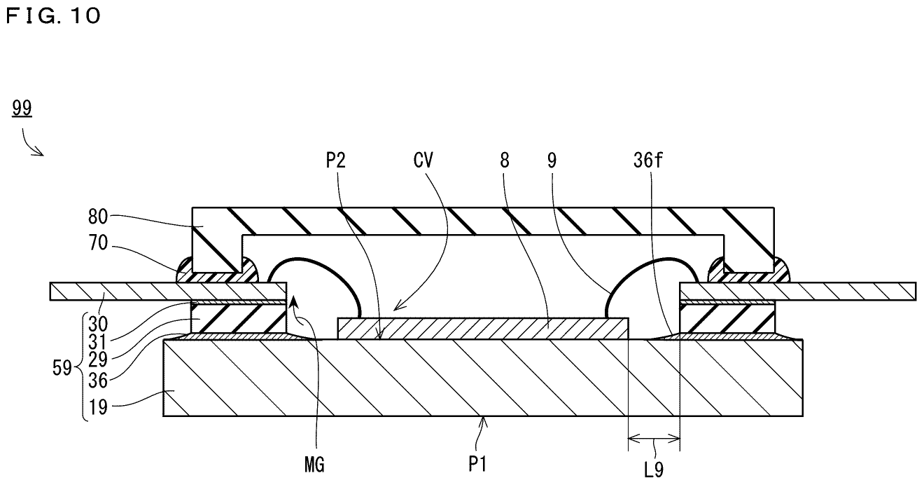

FIG. 9 is a schematic cross-sectional view showing a configuration of a package 59 according to a comparative example. FIG. 10 is a schematic cross-sectional view showing a configuration of a semiconductor module 99 according to the comparative example including the package 59. The package 59 includes a heat dissipating plate 19 and a frame 29 in place of the heat dissipating plate 11 and the ceramic frame 21 (FIG. 3: Embodiment 1). A material for the heat dissipating plate 19 is typically a clad material including a copper tungsten alloy formed by impregnation or a laminated structure of copper and a copper molybdenum alloy. The frame 29 is formed of a ceramic material, and the ceramic material is typically alumina.

The frame 29 is joined to the heat dissipating plate 19 by a brazing material 36. The brazing material 36 has fluidity when being formed and flows inward of an inner peripheral surface (a surface facing the cavity CV) of the frame 29 as illustrated in FIG. 9. A portion of the brazing material 36 having flowed inside the cavity CV forms a fillet 36f at an edge of the cavity CV as illustrated in FIG. 10. A flow distance, that is, a width dimension of the fillet 36f is likely to be greater than 25 μm. To sufficiently reduce a possibility of interference between the fillet 36f and the semiconductor element 8, a distance L9 (FIG. 10) between the semiconductor element 8 and an inner surface of the frame 29 is required to be greater than 25 μm. As a result of such need for large spacing between the semiconductor element 8 and the frame 29, a footprint (an area of a region in which the semiconductor element 8 is mountable) in the cavity CV is reduced. Furthermore, lengths of the wires 9 are increased, typically leading to deterioration of electrical characteristics, such as an unintentional increase in inductance.

An Ag brazing material is typically used as the brazing material 36. When the brazing material 36 contains Ag, Ag migration is likely to occur as indicated by an arrow MG (FIG. 10) upon long-term application of a negative potential to the lead frame 30 relative to a potential of the heat dissipating plate 19. Ag migration might cause insufficient electrical insulation between the heat dissipating plate 19 and the lead frame 30.

When the brazing material 36 is formed, wettability of the brazing material 36 when being molten is required to be ensured. To that end, a plating layer having high wettability to the molten brazing material 36 is required to be formed on a surface of the frame 29 formed of the ceramic material facing the brazing material 36. A metallization layer (not illustrated) for the brazing material 36 is typically required to be formed on the frame 29 as a preparation for formation of the plating layer.

According to Embodiment 1, the ceramic frame 21 and the heat dissipating plate 11 are directly joined together. This eliminates the need for the brazing material 36 (FIG. 10: the comparative example) to join the ceramic frame 21 and the heat dissipating plate 11 together. Interference of the brazing material 36 flowing into the cavity CV with mounting of the semiconductor element 8 is thus avoided. The distance L1 (FIG. 2) between the semiconductor element 8 and the inner surface P3 of the ceramic frame 21 can thus be reduced and can be 25 μm or less, for example. In other words, the semiconductor element 8 can be mounted close to the ceramic frame 21. The footprint in the cavity CV can thus be increased. Furthermore, the lengths of the wires 9 are reduced, typically leading to better electrical characteristics. The brazing material 36 (FIG. 10: the comparative example) is not required to be used, so that a migration phenomenon of Ag contained in the brazing material occurring between the heat dissipating plate 11 and the lead frame 30 can be avoided. A layer to ensure wettability of the brazing material 36 (typically the above-mentioned plating layer and the metallization layer (not illustrated) for the brazing material 36) is not required.

The heat dissipating plate 11 (FIG. 2) may have the side surface P4b flatly connected to the outer surface P4a of the ceramic frame 21. Three examples in which the side surface P4b of the heat dissipating plate 11 is flatly connected to the outer surface P4a of the ceramic frame 21 will herein be described with reference to FIGS. 11 to 13.

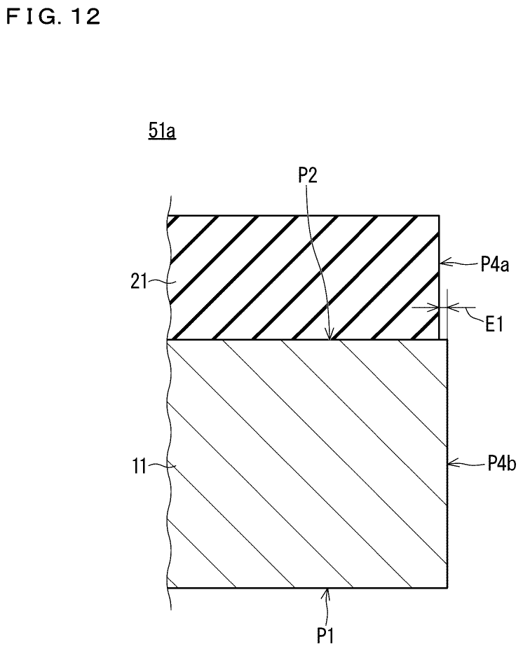

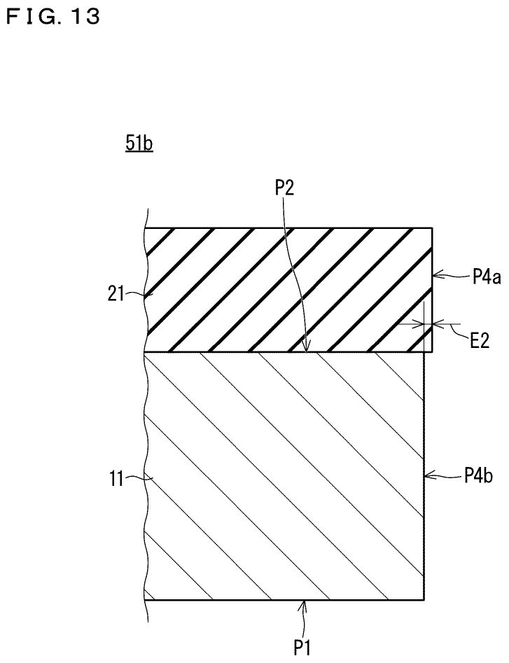

In the package 51 illustrated in FIG. 11, an end (a lower end in the figure) of the outer surface P4a and an end (an upper end in the figure) of the side surface P4b are at a common position, and the position is common to a position of an end (a right end in the figure) of the main surface P2. In a package 51a illustrated in FIG. 12, the end (the lower end in the figure) of the outer surface P4a and the end (the upper end in the figure) of the side surface P4b are at a substantially common position, but the side surface P4b strictly protrudes from the outer surface P4a by a dimension E1, and the dimension E1 is 0.1 mm or less. In a package 51 b illustrated in FIG. 13, the end (the lower end in the figure) of the outer surface P4a and the end (the upper end in the figure) of the side surface P4b are at a substantially common position, but the outer surface P4a strictly protrudes from the side surface P4 b by a dimension E2, and the dimension E2 is 0.1 mm or less.

According to each of the packages 51, 51a, and 51b (FIGS. 11 to 13), stress concentration attributable to misalignment between the heat dissipating plate 11 and the ceramic frame 21 near the end of the main surface P2 can be suppressed. Separation of the heat dissipating plate 11 and the ceramic frame 21 originating from a position near the end of the main surface P2 can thus be prevented.

A direction of (i.e., a direction of a normal vector to) the outer surface P4a at the end (the lower end in each of FIGS. 11 to 13) of the outer surface P4a and a direction of (i.e., a direction of a normal vector to) the side surface P4b at the end (the upper end in each of FIGS. 11 to 13) of the side surface P4 b may be a common direction. While the normal vector is perpendicular to a thickness direction in the example shown in each of FIGS. 11 to 13, the normal vector is not limited to this normal vector and is only required to intersect with the thickness direction.

A portion of the side surface P4b may be a fracture surface in the breaking step (FIG. 8). In this case, the footprint (the area of the region in which the semiconductor element 8 and the like are mountable) is likely to be ensured while breakage of the package 51 originating from a position between the outer surface P4a and the side surface P4b is avoided. A typical form in which the side surface P4b is not flatly connected to the outer surface P4a includes a form in which the outer surface P4a substantially protrudes outward from the side surface P4b (specifically, a form in which the dimension E2>0.1 mm in FIG. 13) and a form in which the outer surface P4a is substantially located inside the side surface P4b (specifically, a form in which the dimension E1>0.1 mm in FIG. 12). In the former form, breakage might originate from the protrusion. In the latter form, an outer edge of the ceramic frame 21 is located inward, so that an inner edge of the ceramic frame 21 is also located inward as long as a width of the ceramic frame 21 is required to be maintained at a predetermined dimension, and, as a result, the footprint is reduced.

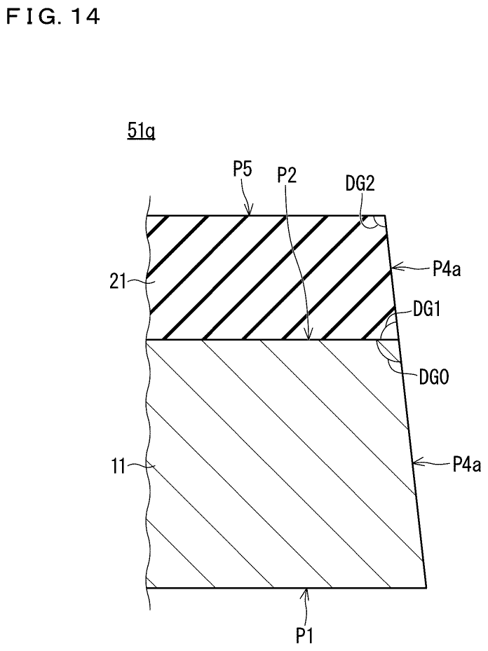

FIG. 14 is a schematic partial cross-sectional view showing a package 51q according to a first modification of the package 51 (FIG. 11). In the package 51q, an angle DG1 between the main surface P2 of the heat dissipating plate 11 and the outer surface P4a of the ceramic frame 21 is an acute angle and is preferably 80° or more and 89° or less and more preferably 80° or more and 85° or less. The ceramic frame 21 may have the upper surface P5 separated from the main surface P2 of the heat dissipating plate 11 by the ceramic frame 21 and connected to the outer surface P4a. The upper surface P5 is a surface substantially parallel to the main surface P2. An angle DG2 between the upper surface P5 and the outer surface P4a may be an obtuse angle in response to the angle DG1 as the acute angle and is preferably 91° or more and 100° or less and more preferably 95° or more and 100° or less. A direction of (i.e., a direction of a normal vector to) the outer surface P4a at the end (the lower end in FIG. 14) of the outer surface P4a and a direction of (i.e., a direction of a normal vector to) the side surface P4b at the end (the upper end in FIG. 14) of the side surface P4b may be a common direction. In this case, an angle DG0 between the main surface P2 of the heat dissipating plate 11 and the side surface P4b of the heat dissipating plate 11 is an obtuse angle in response to the angle DG 1 as the acute angle and is preferably 91° or more and 100° or less and more preferably 95° or more and 100° or less.

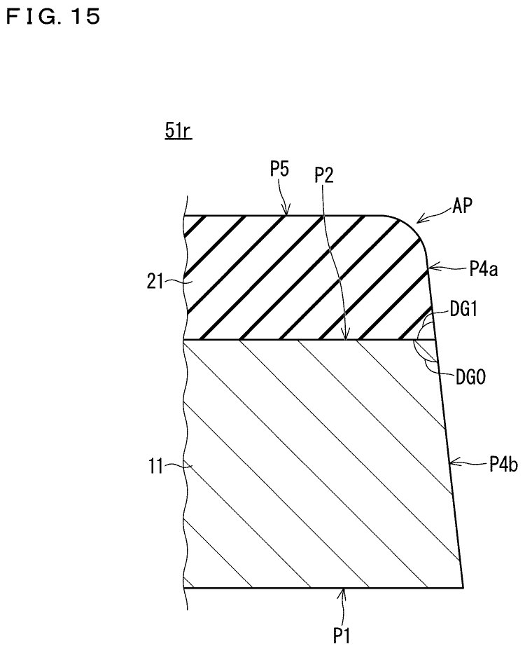

When a corner AP (see FIG. 15) of the outer surface P4a and the upper surface P5 is rounded, the angle DG2 may be an angle between a tangent plane of the outer surface P4a at the lower end (i.e., an end substantially coinciding with an end of the main surface P2) of the outer surface P4a of the ceramic frame 21 in FIG. 14 and the upper surface P5.

When the angle DG1 is the acute angle, an end of the upper surface P5 is recessed inward (leftward in FIG. 14). The end of the upper surface P5 of the ceramic frame 21 is thus less susceptible to shock from outside. Cracking of the ceramic frame 21 caused by the shock is thus prevented. On the other hand, a not-extremely small angle DG1 prevents separation of the heat dissipating plate 11 and the ceramic frame 21 when they are formed by co-firing.

FIG. 15 is a schematic partial cross-sectional view showing a package 51r according to a second modification of the package 51 (FIG. 11). In the modification, the corner AP of the upper surface P5 and the outer surface P4a is rounded. Cracking of the corner AP of the ceramic frame 21 caused by shock is thus prevented. Specifically, the corner AP has a radius of curvature of 0.1 mm or more and 0.5 mm or less. A radius of curvature of 0.1 mm or more sufficiently produces an effect of preventing cracking of the corner AP. A radius of curvature of 0.5 mm or less avoids excessive reduction in area of the upper surface P5 attributable to the rounded corner AP. A joining area of the lead frame 30 (FIG. 3) is thus sufficiently ensured, so that the lead frame 30 can be joined with high strength. While the angle DG1 is preferably in the above-mentioned angle range with reference to FIG. 14, the angle DG1 is not limited to this angle.

In each of FIG. 11 (the package 51), FIG. 14 (the package 51q according to the first modification), and FIG. 15 (the package 51r according to the second modification), while an example in which the outer surface P4a of the ceramic frame 21 and the side surface P4b of the heat dissipating plate 11 are parallel to each other near the end (a right end in each of the figures) of the main surface P2 of the heat dissipating plate 11 is shown, the outer surface P4a and the side surface P4b are not required to be parallel to each other as long as the outer surface P4a and the side surface P4b are connected to each other. For example, while a case where an equation DG1=180°−DG0 holds true is illustrated in FIG. 15, an inequality DG1<180°−DG0 may hold true. Furthermore, at least one of the outer surface P4a and the side surface P4b connected to each other may be a curved surface. In other words, the outer surface P4a and the side surface P4b may be connected to each other, and the outer surface P4a and/or the side surface P4b may be a curved surface/curved surfaces. The same applies to the above-mentioned other packages.

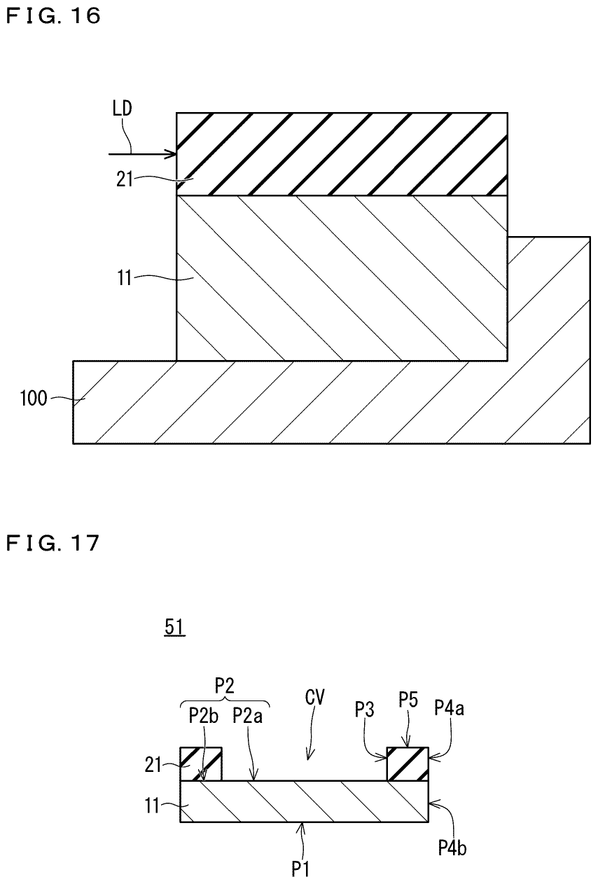

FIG. 16 is a schematic partial cross-sectional view showing a joining strength test conducted on the heat dissipating plate 11 and the ceramic frame 21. In the test, a simple laminated body in which the heat dissipating plate 11 and the ceramic frame 21 had the same shape in an in-plane direction as illustrated in FIG. 16 was used as a sample for convenience of work. The laminated body was fixed by disposing the laminated body at a corner of an L-shaped lower jig 100. As a test apparatus for joining strength, Autograph®“AG-X plus” from SHIMADZU CORPORATION was used.

As a powder raw material for the heat dissipating plate 11, mixed powder of Cu powder having an average particle size of 5 μm and W powder having an average particle size of 3 μm was used, and a ratio of the Cu powder to the W powder was adjusted so that a volume ratio of Cu to W after firing was 50/50 (i.e., Cu and W had an equal volume). As powder raw materials for the ceramic frame 21, Al₂O₃ powder, SiO₂ powder, and MnO₂ powder were used. Pressing pressure between the first green sheet 11G (the heat dissipating plate) and the second green sheet 21G (the ceramic frame) during lamination was 50 kgf/cm². A co-firing step of the heat dissipating plate 11 and the ceramic frame 21 was performed by maintaining a maximum temperature of 1250° C. for two hours.

The joining strength test was conducted by applying a lateral load LD (FIG. 16) of 1000 N. The heat dissipating plate 11 and the ceramic frame 21 were not separated from each other by application of this lateral load LD. The lateral load LD corresponds to shear strength of 12 N/mm² (1.2 kgf/mm²) or more at the joined surface, and the shear strength is sufficiently high in practical use of the package.

A temperature cycling test was also conducted on a similar sample to that in FIG. 17 to evaluate separation resistance of the ceramic frame 21 and the heat dissipating plate 11 to repeated thermal expansion. Specifically, a temperature cycling test was conducted by repeating a step of maintaining a predetermined temperature for 15 minutes for 100 cycles in conformity to an MIL standard 883K, a method number 1010, and a condition C. In this test, the absence of separation of the ceramic frame 21 and the heat dissipating plate 11 was visually confirmed.

### Embodiments 2 to 6

FIG. 17 is a schematic cross-sectional view showing a configuration of the heat dissipating plate 11 and the ceramic frame 21 of the package 51 (FIG. 3) according to Embodiment 1 described above. Illustration in FIG. 17 is more simplified than illustration in FIG. 3 for convenience of description. Configurations of packages 52 to 56 respectively according to Embodiments 2 to 6 will be described below while being compared with the configuration in FIG. 17.

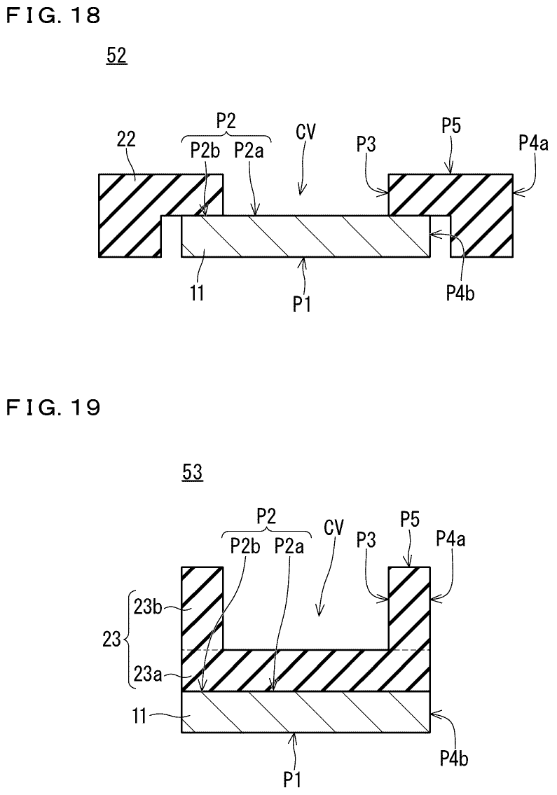

FIG. 18 is a schematic cross-sectional view showing the configuration of the package 52 according to Embodiment 2. The package 52 includes a ceramic frame 22 in place of the ceramic frame 21 (FIG. 17). The ceramic frame 22 (specifically, an inner portion thereof) is disposed on the main surface P2 of the heat dissipating plate 11. As for a position in a thickness direction, the ceramic frame 22 extends from a position above the main surface P2 of the heat dissipating plate 11 into a range between the main surface P2 and the heat dissipating surface P1 of the heat dissipating plate 11. The ceramic frame 22 may further extend and extends to a position of the heat dissipating surface P1 of the heat dissipating plate 11 in an example shown in FIG. 18. The ceramic frame 22 is away from the side surface P4b of the heat dissipating plate 11.

FIG. 19 is a schematic cross-sectional view showing the configuration of the package 53 according to Embodiment 3. The package 53 includes a ceramic frame 23 in place of the ceramic frame 21 (FIG. 17). The ceramic frame 23 includes a plate-like base portion 23a disposed on the main surface P2 of the heat dissipating plate 11 and a frame portion 23b fixed to the heat dissipating plate 11 via the base portion 23a. A boundary (dashed lines in the figure) between the base portion 23a and the frame portion 23b may be an imaginary boundary. The frame portion 23b has the inner surface P3. The main surface P2 of the heat dissipating plate 11 includes the joined surface P2b directly joined to the base portion 23a of the ceramic frame 23 in Embodiment 3. In an example shown in FIG. 19, the entire main surface P2 is the joined surface P2b. The cavity surface P2a of the heat dissipating plate 11 faces the cavity CV via the base portion 23a of the ceramic frame 23 in Embodiment 3. It can thus be said that the cavity surface P2a faces the cavity CV also in Embodiment 3.

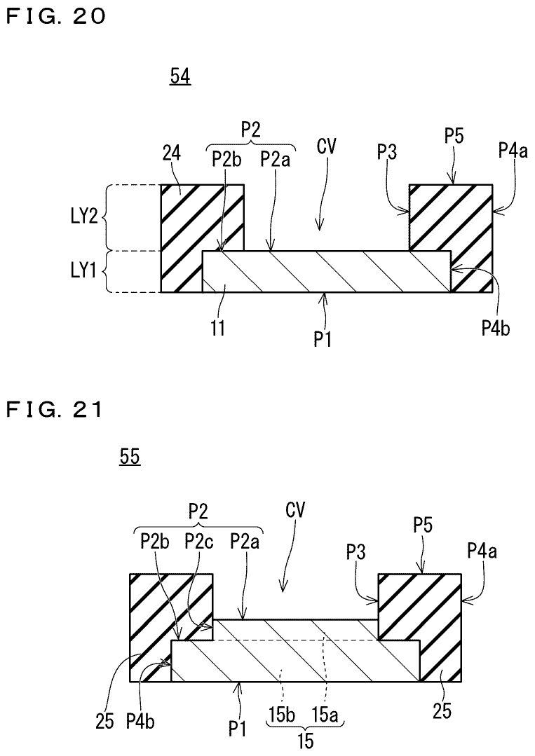

FIG. 20 is a schematic cross-sectional view showing the configuration of the package 54 according to Embodiment 4. The package 54 includes a ceramic frame 24 in place of the ceramic frame 21 (FIG. 17). The ceramic frame 24 (specifically, an inner portion thereof) is disposed on the main surface P2 of the heat dissipating plate 11. As for a position in a thickness direction, the ceramic frame 24 extends from a position above the main surface P2 of the heat dissipating plate 11 into a range between the main surface P2 and the heat dissipating surface P1 of the heat dissipating plate 11. The ceramic frame 24 may further extend and extends to a position of the heat dissipating surface P1 of the heat dissipating plate 11 in an example shown in FIG. 20. The side surface P4b of the heat dissipating plate 11 includes a joined surface directly joined to the ceramic frame 24. While the entire side surface P4b is the joined surface in the example shown in FIG. 20, only a portion of the side surface P4b may be the joined surface.

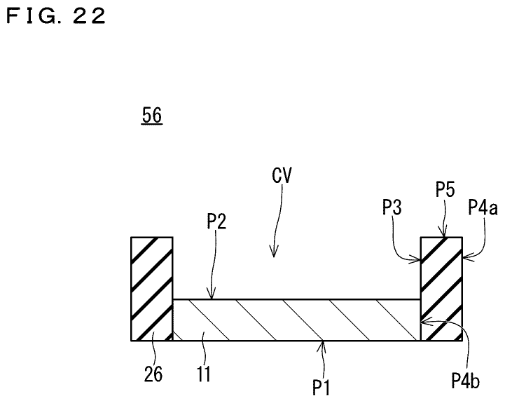

The package 54 can be manufactured by firing a laminated body of a lower layer LY1 and an upper layer LY2. The lower layer LY1 is formed as described below, for example. First, a first unfired layer formed of a material to be the ceramic frame 24 by being fired is formed. Next, a through hole corresponding to a region in which the heat dissipating plate 11 is disposed is formed in the first unfired layer using a die. Next, a second unfired layer including a portion to be the heat dissipating plate 11 by being fired is laminated on the first unfired layer to cover the above-mentioned through hole. Next, the above-mentioned portion of the second unfired layer is pushed into the above-mentioned through hole using the die again. Next, a portion of the second unfired layer not pushed using the die, that is, a portion of the second unfired layer remaining on an upper surface of the first unfired layer is removed. The lower layer LY1 is thus obtained. The upper layer LY2 is obtained by removing a portion corresponding to the cavity CV from an unfired layer formed of a material to be the ceramic frame 24 by being fired. The laminated body of the lower layer LY1 and the upper layer LY2 is fired to obtain the package 54. The package 55 (FIG. 21) and the package 56 (FIG. 22) described below can be manufactured by a similar method.

FIG. 21 is a schematic cross-sectional view showing the configuration of the package 55 according to Embodiment 5. The package 55 includes a heat dissipating plate 15 and a ceramic frame 25 in place of the heat dissipating plate 11 and the ceramic frame 21 (FIG. 17). The ceramic frame 25 (specifically, an inner portion thereof) is disposed on the main surface P2 of the heat dissipating plate 15. The heat dissipating plate 15 includes a support portion 15b and a cavity portion 15a disposed on a portion of the support portion 15b. A boundary (a dashed line in FIG. 21) between the cavity portion 15a and the support portion 15b may be an imaginary boundary. The main surface P2 of the heat dissipating plate 15 includes the cavity surface P2a of the cavity portion 15a and the joined surface P2b of the support portion 15b. In the main surface P2 of the heat dissipating plate 15, the cavity surface P2a and the joined surface P2b are at different positions in a thickness direction, and the position of the latter is closer to the heat dissipating surface P1. The cavity surface P2a and the joined surface P2b may be surfaces substantially parallel to each other. The main surface P2 may further include a side wall surface P2c of the cavity portion 15a connecting the cavity surface P2a and the joined surface P2b. The side wall surface P2c of the heat dissipating plate 15 may extend substantially along the thickness direction. The side wall surface P2c may be a joined surface directly joined to the ceramic frame 25. The side surface P4b of the support portion 15b may include a joined surface directly joined to the ceramic frame 25.

FIG. 22 is a schematic cross-sectional view showing the configuration of the package 56 according to Embodiment 6. The package 56 includes a ceramic frame 26 in place of the ceramic frame 21 (FIG. 17). The ceramic frame 26 is disposed on the side surface P4b of the heat dissipating plate 11. The side surface P4b includes a joined surface directly joined to the ceramic frame 26. While the entire side surface P4b is the joined surface in an example shown in FIG. 22, only a portion of the side surface P4b may be the joined surface.

The lead frame 30 (FIG. 3) may be applied to each of the packages 52 to 56 as in the package 51. The metallization layer 31 (FIG. 3) may be applied to each of the packages 52 to 56 as in the package 51. In any of cases of the packages 51 to 56, another metallization layer not for the lead frame 30 may be formed on the upper surface P5 of the ceramic frame in place of or in addition to the metallization layer 31 for the lead frame 30. A material for the other metallization layer may be similar to the above-mentioned material for the metallization layer 31.

Next, comparison among the packages 51 to 56 will be described below.

First, joining strength will be described below.

In a step of laminating the green sheets for manufacture of each of the packages 51 to 56 (see FIG. 5 in a case of the package 51, for example), pressure is applied in a lamination direction, that is, a thickness direction. A green structure obtained in the lamination step is pressed with a large load along the thickness direction as necessary, so that larger pressure is easily applied in the thickness direction. Application of the pressure before the step of co-firing the heat dissipating plate and the ceramic frame contributes to an increase in joining strength between them. The pressure is applied perpendicularly to the main surface P2, so that joining strength can most effectively be improved when the main surface P2 includes the joined surface. Pressure at the joined surface in this case may be 10 kgf/cm² to 150 kgf/cm². The pressure falls within the range, so that sufficient joining strength can be obtained after firing while deformation and misalignment of the green sheets are suppressed. On the other hand, such pressure is less likely to be applied to the side surface P4b of the heat dissipating plate. It is difficult to apply pressure by additional pressing. The joining strength is thus likely to be smaller at the joined surface included in the side surface P4b of the heat dissipating plate than at the joined surface included in the main surface P2.

From the foregoing, the package 56 having only the joined surface included in the side surface P4b is likely to have relatively small joining strength over the entire joined surface. This can result in a problem of reduction in airtightness of the package caused because the joined surface becomes a leak path. In contrast, in each of the packages 51 to 55, at least a portion of the joined surface is included in the main surface P2, so that large joining strength is at least partially likely to be ensured. The occurrence of leakage of the package can thus be suppressed. In particular, in each of the packages 51 to 53, the entire joined surface is included in the main surface P2, so that large joining strength is likely to be ensured over the entire joined surface. The occurrence of leakage of the package can thus more surely be suppressed.

If an increase in size of the package is allowed without limitation, an increase in area of the joined surface is also allowed without limitation, and, as a result, a problem attributable to joining strength is less likely to occur. The size of the package, however, is typically limited. In comparison among the packages 51 to 53, the packages 51 and 52 are preferable in terms of a small size in the thickness direction, the packages 51 and 53 are preferable in terms of a small size in an in-plane direction, and the package 51 is preferable in terms of a small size in both of the directions.

Secondly, heat dissipation characteristics will be described. As described above, the size of the package is typically limited. To efficiently remove heat from the semiconductor element 8 (FIG. 2) mounted to the main surface P2 downward in FIG. 2 under such limitation, it is desirable to dispose the heat dissipating plate 11 as widely as possible in the in-plane direction in a region below the main surface P2 in FIG. 2. The packages 51 to 53 are preferable in this light. In comparison among them, the packages 51 and 52 are preferable as they can avoid an increase in thermal resistance attributable to the ceramic frame interposed between the semiconductor element 8 (FIG. 2) and the heat dissipating plate 11.

From the foregoing, when viewpoints of joining strength and heat dissipation characteristics are both taken into account, the package 51 is often preferable from among the packages 51 to 56 although preferability depends on a use of the package.

### Analysis on Joined Surface of Heat Dissipating Plate to Ceramic Frame

A result of analysis on the joined surface of the heat dissipating plate to the ceramic frame formed by co-firing will be described below.

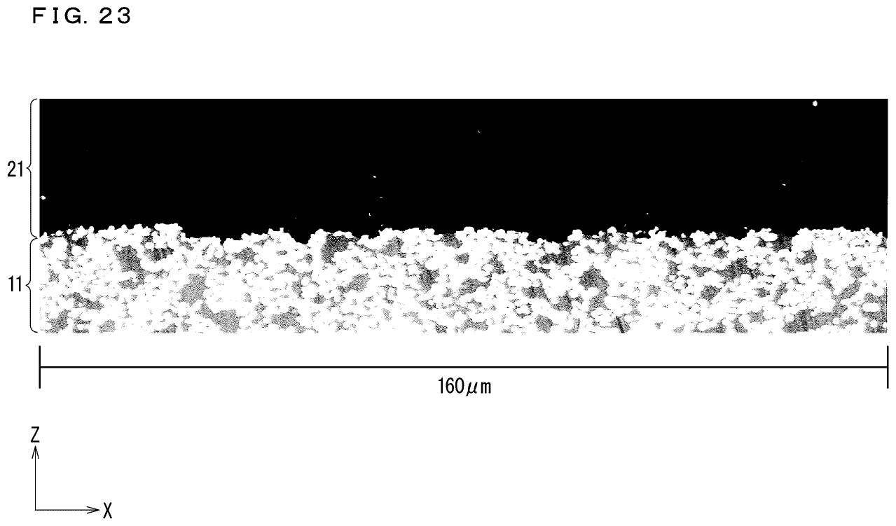

FIG. 23 is an electron micrograph showing a cross section of a portion of the joined surface (the joined surface P2b in FIG. 3) of the heat dissipating plate 11 to the ceramic frame 21 in a test piece manufactured under the same condition as test pieces used in the joining strength test and the temperature cycling test described above. The electron micrograph in the figure is through observation at an acceleration voltage of 15 kV, and the same applies to electron micrographs in the other figures. In the figure, a Z direction is a direction in which the heat dissipating plate and the ceramic frame oppose each other via the joined surface. The Z direction thus corresponds to the thickness direction in FIG. 17 (a vertical direction in FIG. 17) and corresponds to the in-plane direction in FIG. 22 (a horizontal direction in FIG. 22), for example. An X direction is a direction perpendicular to the Z direction. The X direction thus corresponds to the in-plane direction in FIG. 17 (a horizontal direction in FIG. 17) and corresponds to the thickness direction in FIG. 22 (a vertical direction in FIG. 22), for example. Powder raw materials for the heat dissipating plate 11 and the ceramic frame 21 were the same as those described with reference to FIG. 16.

An area ratio of the refractory metal (at least one refractory metal selected from the group consisting of W and Mo and being W in a sample observed in FIG. 23) in the joined surface of the heat dissipating plate 11 is greater than a volume ratio of the refractory metal in the heat dissipating plate 11. The volume ratio may be calculated using a value of the area ratio of the refractory metal in the micrograph of the cross section of the heat dissipating plate 11, and, in calculation, a range similar to a range of an area (approximately 160 μm×approximately 20 μm) of the heat dissipating plate 11 shown in FIG. 23 may be used, and equations W=50% and Cu=50% hold true in this example. White portions are W and grey portions are Cu in the heat dissipating plate 11 shown in the micrograph, and there is a sufficient difference in contrast between them, so that the area ratio can be calculated by binarization of the image. Image processing software may be used for binarization. As the image processing software, “ImageJ” may be used, for example.

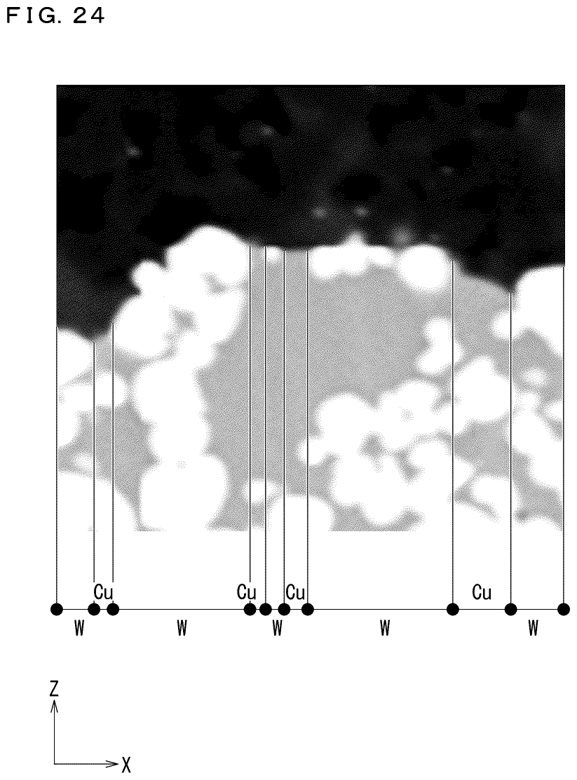

In the above-mentioned cross section, the joined surface macroscopically extends along a straight line and microscopically defines an irregular boundary between the heat dissipating plate and the ceramic frame. The macroscopic straight line may herein be obtained by straight-line approximation of the microscopic boundary in a range of a dimension on the order of hundreds of micrometers and, in FIG. 23, for example, may be obtained by straight-line approximation of the irregular boundary in a range of 160 μm in the X direction. The straight line may be considered as a straight line extending substantially along the in-plane direction (the horizontal direction in FIG. 17) in the structure in FIG. 17 and may be considered as a straight line extending substantially along the thickness direction (the vertical direction in FIG. 22) in the structure in FIG. 22, for example. Irregularities are easily observable by observation of a cross section with a scanning electron microscope having a normal resolution. For example, a cross section in which irregularities are sufficiently distinguishable as in FIG. 23 is sufficiently observable when a resolution of approximately 0.1 μm (or less than 0.1 μm) is ensured. The above-mentioned irregular boundary includes a copper section formed of copper and a refractory metal section formed of the least one refractory metal. In the micrograph in FIG. 23, a portion formed of the refractory metal (specifically W) is white, a portion formed of copper is grey, and there is a large difference in contrast between them, so that it is easy to distinguish between the copper section and the refractory metal section. Ratios of the refractory metal and copper to the boundary can simply be obtained by projecting the refractory metal section and the copper section of the boundary onto the above-mentioned macroscopic straight line, that is, an X axis as illustrated in FIG. 24. In this example, the ratio of the refractory metal section was 65.3% and the ratio of the copper section was 34.7% in the projection of the boundary onto the above-mentioned straight line.

From the foregoing, the ratio of the refractory metal section in the projection of the boundary onto the above-mentioned straight line is estimated to be 65.3%, the volume ratio of the refractory metal in the heat dissipating plate 11 is estimated to be 50%, and the former is greater than the latter. In this example, the ratio was 1.3 times the volume ratio. The magnification is not limited to 1.3 and, for example, may be 1.3 or more as the magnification in this example. The magnification is preferably 1.1 or more to obtain an effect produced by a high magnification. According to the inventors'study, the above-mentioned ratio of the refractory metal section can be increased by increasing a firing temperature and a firing time when the package is manufactured. Application of the pressure to the green structure in the lamination direction (thickness direction) described above is also considered to be able to contribute to improvement in the ratio. An increase in the ratio can bring a coefficient of thermal expansion of a portion of the heat dissipating plate 11 facing the ceramic frame 21 in a direction of the above-mentioned straight line closer to a coefficient of thermal expansion of the ceramic frame 21. Separation of the heat dissipating plate 11 and the ceramic frame 21 from each other is thus prevented.

It is considered that a structure in which the heat dissipating plate 11 and the ceramic frame 21 are joined together is obtained by laminating an unfired ceramic frame 21 as a green member on an already fired heat dissipating plate 11 and firing the green member. According to the inventors'study, however, joining strength between them is expected to be extremely small compared with a case where the heat dissipating plate 11 and the ceramic frame 21 are formed by co-firing. This is presumably because the above-mentioned ratio is reduced. A reason why the ratio is reduced when co-firing is not performed will be described below by taking, as an example, a case where the heat dissipating plate is formed of an alloy of Cu and W, that is, the heat dissipating plate is a CuW plate.

The CuW plate is typically formed through a step in which W particles and molten Cu coexist at a high temperature exceeding a melting point of Cu. It is herein well-known that molten Cu has high wettability to solid W. It is considered that, in terms of wettability, a heat dissipating plate 11 is likely to have a Cu rich surface due to spreading Cu. If the unfired ceramic frame as the green member is laminated on the CuW plate having such a Cu rich surface, and the green member is fired, the ratio of Cu to the joined surface is considered to be increased. In other words, the ratio of W is considered to be reduced. The above-mentioned ratio is thus considered to be reduced.

In contrast, when co-firing is used, unfired W particles (more generally refractory metal particles) in the first green sheet 11G (corresponding to the unfired heat dissipating plate 11) and unfired ceramic particles in the second green sheet 21G (corresponding to the unfired ceramic frame 21) are likely to be arranged to be in contact with each other or close to each other in the laminated body SG (FIG. 6) before firing. As a result, the ratio of W to the joined surface after the firing step is likely to be increased. The above-mentioned ratio is thus considered to be increased.

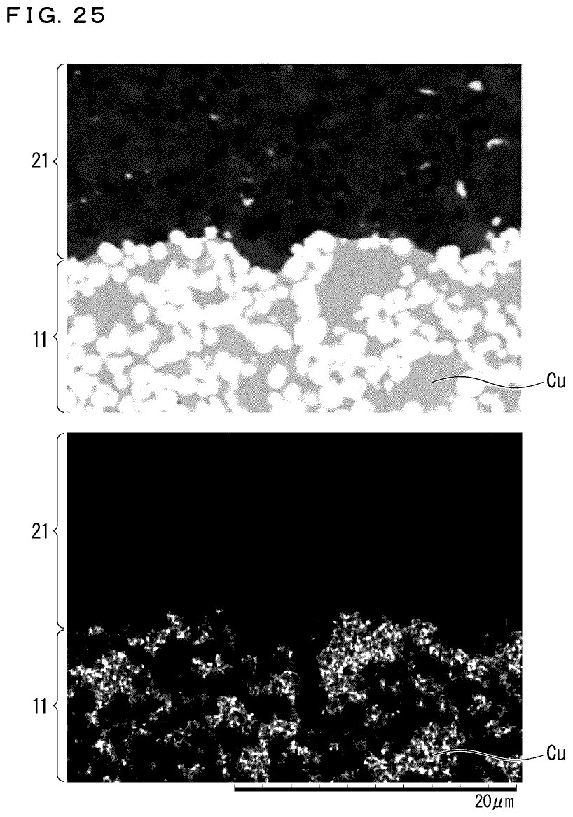

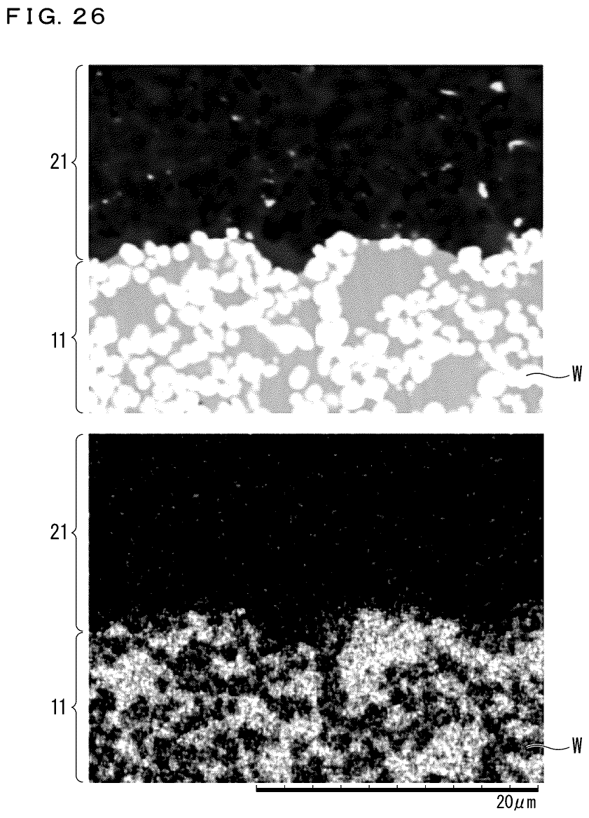

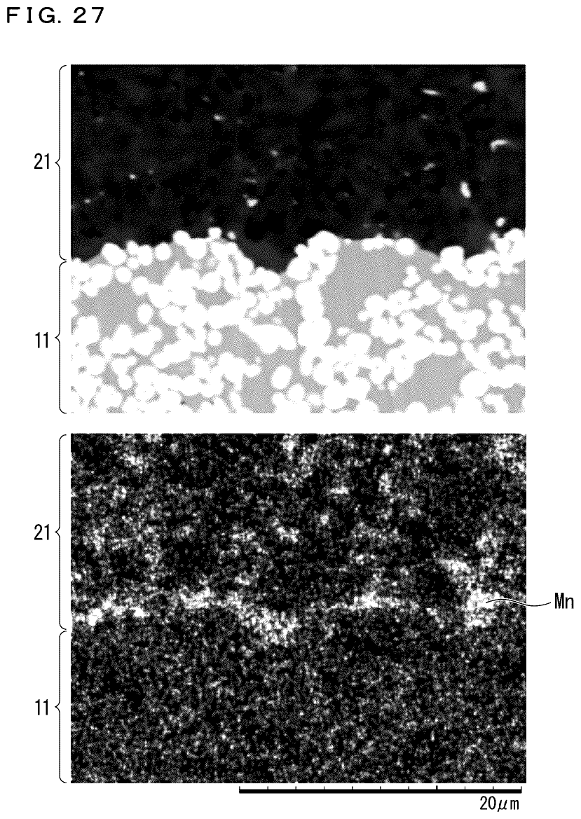

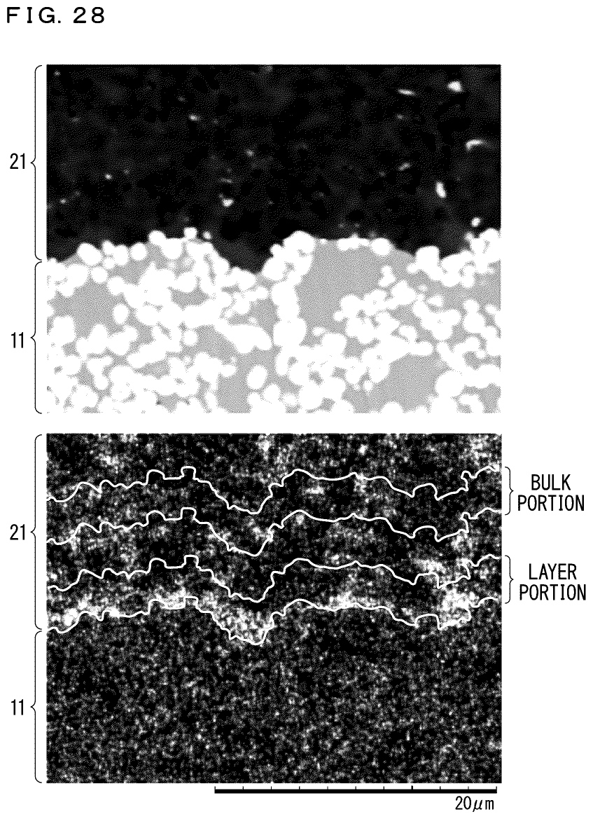

FIGS. 25 to 27 are diagrams showing Cu, W, and Mn element distribution (bottom) near the joined surface of the heat dissipating plate 11 to the ceramic frame 21 in test pieces manufactured under the same condition as the test pieces used in the joining strength test and the temperature cycling test described above together with electron micrographs (top) corresponding to views in the distribution maps. FIG. 28 is a diagram showing a layer portion and a bulk portion, which will be described in detail below, for the Mn element distribution shown at the bottom of FIG. 27. In the element distribution map at the bottom, a portion in which each element has a high concentration is displayed in white. As can be seen from a result of the Mn element distribution map shown in FIG. 27, Mn elements are unevenly distributed in a layer portion (FIG. 28) of the ceramic frame 21 facing the joined surface of the heat dissipating plate 11. The element distribution was measured by scanning electron microscopic energy dispersive X-ray spectroscopy (SEM-EDX). As a measuring apparatus, Miniscope® “TM3030” from Hitachi High-Tech Corporation was used.

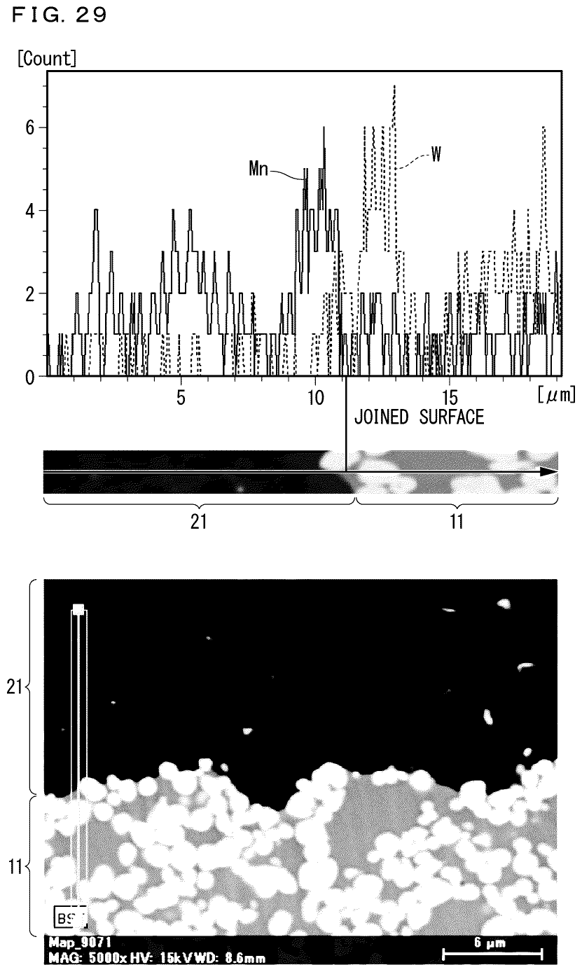

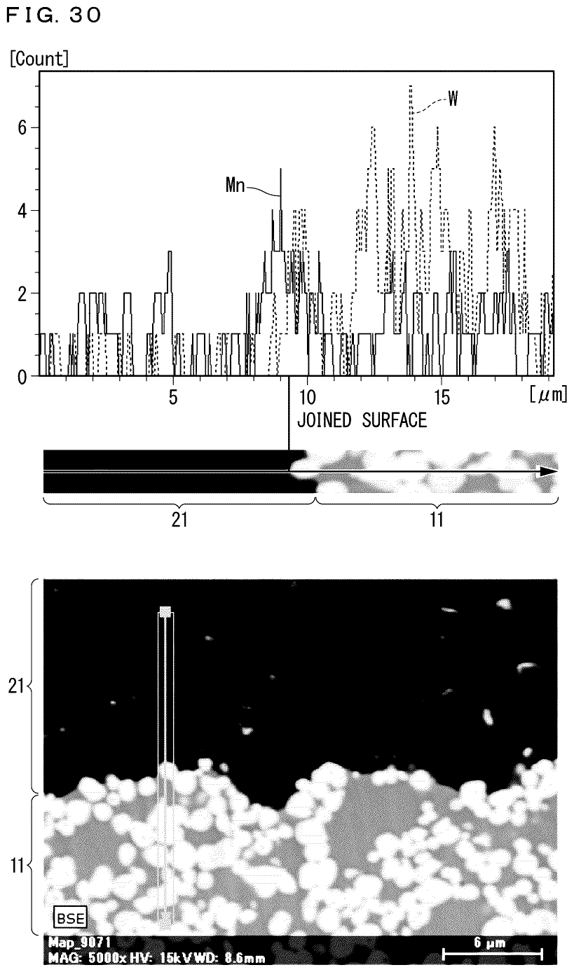

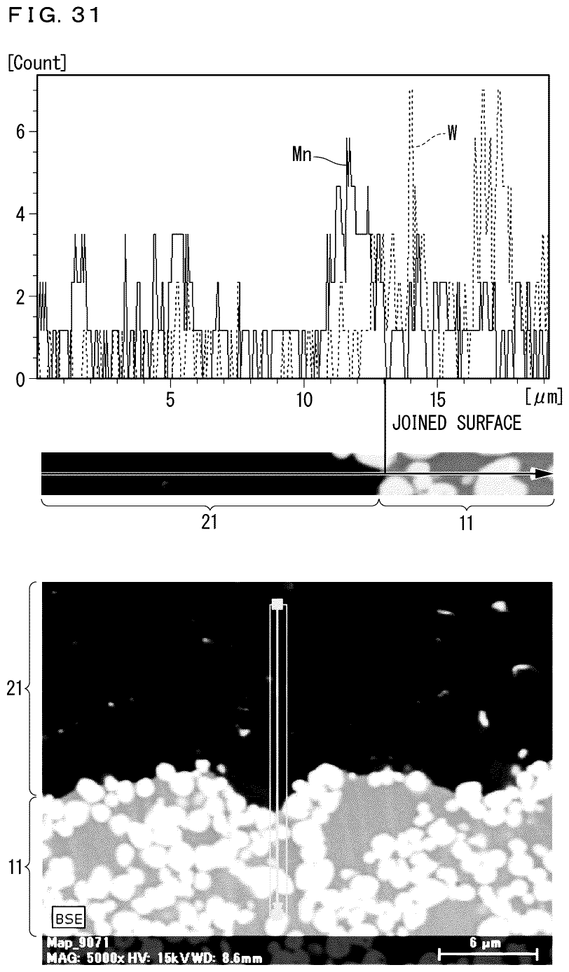

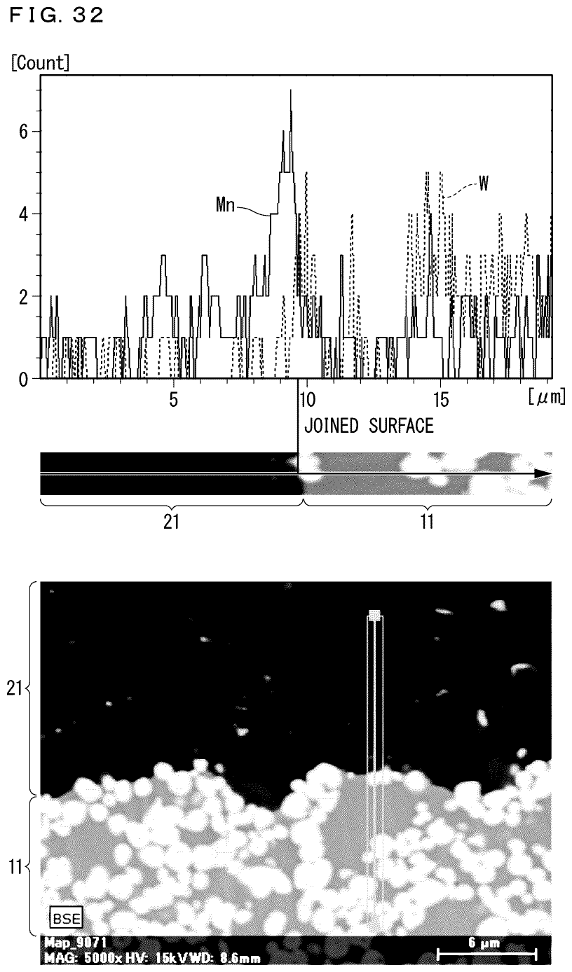

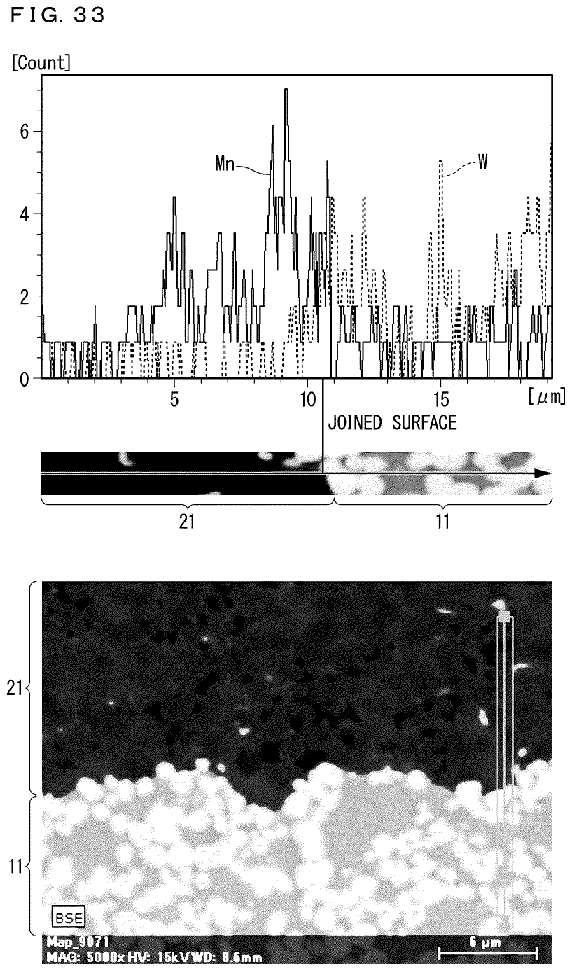

FIGS. 29 to 33 are each a graph (top) showing a depth profile of a count by SEM-EDX in a direction perpendicular to the joined surface (i.e., the Z direction in FIG. 23) in an Mn element analysis together with the electron micrograph shown in FIG. 27 to which a rectangular region corresponding to the profile has been added (bottom) and the region (middle) disposed to match a horizontal axis of the graph. The count corresponds to an Mn element concentration (e.g., a concentration represented by wt %) in the ceramic frame 21. A depth profile of W is also shown in the graph at the top. The depth profile shown in each of FIGS. 29 to 33 is a result of measurement for five regions at different positions in a direction perpendicular to the thickness direction. In the Mn element distribution map, an Mn concentration profile for a depth from the joined surface into the ceramic frame was acquired to pass through a portion in which Mn is distributed in the layer portion.

In the Mn element distribution map (bottom in FIG. 28), a portion of the ceramic frame 21 located at a depth of 3 μm or less from the joined surface of the heat dissipating plate 11, that is, in a depth range of 3 μm including a position at a depth of 3 μm or less from the joined surface into the ceramic frame 21 is herein defined as the layer portion. The layer portion of the ceramic frame 21 is located near the joined surface of the heat dissipating plate 11, so that a composition thereof is strongly affected by being joined to the heat dissipating plate 11. On the other hand, a portion of the ceramic frame 21 separated from the joined surface by the layer portion and having a sufficient depth from the joined surface is a substantially unaffected bulk region in contrast to the foregoing. According to the inventors'study, a portion at a depth of 6 μm or more is included in the above-mentioned bulk region by being located at a sufficient depth. A portion in a depth range of 3 μm including a position at a depth of 6 μm or more and 9 μm or less from the joined surface into the ceramic frame 21 is herein referred to as the bulk portion as a representative portion in the bulk region.

As can be seen from each of results in FIGS. 29 to 33, an Mn concentration profile for a depth from the joined surface of the heat dissipating plate 11 into the ceramic frame 21 includes a maximum peak located in the layer portion (i.e., at a depth of 3 μm or less from the joined surface). Thus, when only a single maximum peak was observed, the maximum peak was located in the layer portion, and, when a plurality of maximum peaks having the same maximum count were observed, the plurality of maximum peaks included a maximum peak located in the layer portion. As can be seen from each of FIGS. 29 to 33, the Mn concentration profile is considered to have bulk property at a position at a depth of approximately 6 μm or more from the joined surface. A representative value in the bulk portion in the Mn concentration profile can thus be estimated by a peak in a depth range of 3 μm including the position at a depth of 6 μm or more and 9 μm or less from the joined surface into the ceramic frame 21, for example. The above-mentioned maximum peak located in the layer portion may be 150% or more of the representative value in the bulk portion as in each of FIGS. 29 to 33. According to the inventors'study, the percentage can be increased by increasing the firing time when the package is manufactured.

As can be seen from each of the results in FIGS. 29 to 33, the Mn element concentration is higher in the layer portion than in the bulk portion. In response to this, in SEM-EDX (the element distribution map) of Mn, a count per unit area is higher in the layer portion than in the bulk portion. In a common range in the in-plane direction, the count is higher in the layer portion than in the bulk portion. Ensuring a dimension in the above-mentioned range in which the count is summed up of approximately several tens of micrometers (e.g., a dimension similar to a lateral dimension in a view of FIG. 28) will typically suffice. The Mn element concentration in the layer portion may be 150% or more of the Mn element concentration in the bulk portion. The percentage can be obtained by calculating a percentage of a total count in the layer portion relative to a total count in the bulk portion in the above-mentioned common range in the in-plane direction, for example.

According to the inventors'study, it is considered that joining strength between the ceramic frame 21 and the heat dissipating plate 11 can be increased by locally increasing an Mn concentration in the layer portion of the ceramic frame 21. This is presumably because Mn atoms in the ceramic frame 21 and metal atoms in the heat dissipating plate 11 may bind together, although a mechanism has not yet been verified. The above-mentioned effect of increasing joining strength is more sufficiently obtained when the maximum peak located in the layer portion is 150% or more of the representative value in the bulk portion. It is considered that the percentage has no particular upper limit in terms of the effect and can be increased to approximately 1000%, for example, when another viewpoint is taken into account.

While the disclosure has been shown and described in detail, the foregoing description is in all aspects illustrative and not restrictive. It is therefore understood that numerous modifications and variations can be devised.

What is claimed is:

1. A package having a cavity, the package comprising:
a heat dissipating plate formed of a first sintered material containing a metal, the heat dissipating plate having a main surface, a heat dissipating surface opposite the main surface, and a side surface between the heat dissipating surface and the main surface, the main surface including a cavity surface facing the cavity; and
a ceramic frame having an inner surface surrounding the cavity and an outer surface opposite the inner surface, wherein
the main surface of the heat dissipating plate includes a joined surface directly joined to the ceramic frame.

2. The package according to claim 1, wherein
the side surface of the heat dissipating plate is not directly joined to the ceramic frame.

3. The package according to claim 1, wherein
the first sintered material is a sintered metal material.

4. The package according to claim 1, wherein
the first sintered material contains copper and at least one refractory metal selected from the group consisting of tungsten and molybdenum.

5. The package according to claim 4, wherein
in a cross section of at least a portion of the joined surface, the joined surface macroscopically extends along a straight line and microscopically defines an irregular boundary between the heat dissipating plate and the ceramic frame, the boundary including a copper section formed of the copper and a refractory metal section formed of the at least one refractory metal, and
a ratio of the refractory metal section in a projection of the boundary onto the straight line is greater than a volume ratio of the at least one refractory metal in the heat dissipating plate.

6. The package according to claim 4, further comprising
a metallization layer disposed on an upper surface of the ceramic frame and formed of a second sintered material, the second sintered material containing copper in a higher volume ratio than the first sintered material for the heat dissipating plate.

7. The package according to claim 1, wherein
the ceramic frame contains Mn,
in an Mn element distribution map, the ceramic frame includes a layer portion and a bulk portion, the layer portion being in a depth range of 3 μm including a position at a depth of 3 μm or less from the joined surface into the ceramic frame, the bulk portion being in a depth range of 3 μm including a position at a depth of 6 μm or more and 9 μm or less from the joined surface into the ceramic frame, and
an Mn element concentration is higher in the layer portion than in the bulk portion.

8. The package according to claim 1, wherein
the ceramic frame contains Mn,
the ceramic frame includes a layer portion and a bulk portion, the layer portion being located at a depth of 3 μm or less from the joined surface, the bulk portion being separated from the joined surface by the layer portion, and
an Mn concentration profile for a depth from the joined surface into the ceramic frame includes a maximum peak located in the layer portion.

9. The package according to claim 8, wherein
in the Mn concentration profile for the depth, the maximum peak is 150% or more of a representative value in the bulk portion.

10. The package according to claim 1, wherein
the joined surface of the heat dissipating plate does not contain silver.

11. The package according to claim 1, wherein
the side surface of the heat dissipating plate is connected to the outer surface of the ceramic frame.

12. The package according to claim 11, wherein
the side surface of the heat dissipating plate is flatly connected to the outer surface of the ceramic frame.

13. The package according to claim 1, wherein
the main surface of the heat dissipating plate and the outer surface of the ceramic frame form an acute angle.

14. The package according to claim 1, wherein
the ceramic frame has an upper surface separated from the main surface of the heat dissipating plate by the ceramic frame and connected to the outer surface, and
a corner of the upper surface of the ceramic frame and the outer surface of the ceramic frame has a radius of curvature of 0.1 mm or more and 0.5 mm or less.

15. The package according to claim 1, further comprising
a metal terminal disposed on an upper surface of the ceramic frame.

16. A semiconductor module comprising:
the package according to claim 1; and
a semiconductor element mounted to the cavity surface of the main surface of the heat dissipating plate, wherein
a distance between the semiconductor element and the inner surface of the ceramic frame is 25 μm or less.

17. A package manufacturing method for manufacturing the package according to claim 1, the package manufacturing method comprising:
forming a green structure in which a first green member to be the heat dissipating plate by being fired and a second green member to be the ceramic frame by being fired are combined; and
firing the green structure.

18. The package manufacturing method according to claim 17, wherein
the forming of the green structure includes forming the second green member, the forming of the second green member including removing a portion corresponding to the cavity from a green sheet to be at least a portion of the second green member.

19. The package manufacturing method according to claim 17, wherein
the first green member is formed using first metal powder containing copper and at least one refractory metal selected from the group consisting of tungsten and molybdenum, and
the green structure includes an additional layer to be a metallization layer on an upper surface of the ceramic frame by being fired, the additional layer being formed using second metal powder containing copper and at least one refractory metal selected from the group consisting of tungsten and molybdenum, the second metal powder containing copper in a higher volume ratio than the first metal powder.
